(19) United States
(12) Patent Application Publication
(10) Pub. No.: US 2009/0084409 A1
(43) Pub. Date: Apr. 2, 2009

(54) Cleaning apparatus, cleaning system using cleaning apparatus, cleaning method of substrate-to-be-cleaned

(75) Inventors: Ryoichi Okura, Tokyo (JP); Tatsuro Yoshida, Tokyo (JP); Yoshishige Takikawa, Tokyo (JP); Osamu Nakamura, Tokyo (JP)

Correspondence Address: KRATZ, QUINTOS & HANSON, LLP, 1420 K Street, N.W., Suite 400, WASHINGTON, DC, 20005, US

(73) Assignee: REALIZE ADVANCED TECHNOLOGY LIMITED, Tokyo (JP)

(21) Appl. No.: 11/792,994

(22) PCT Filed: Dec. 14, 2005
(86) PCT No.: PCT/JP05/22951

§ 371 Date: Apr. 3, 2008

(30) Foreign Application Priority Data
Dec. 14, 2004 (JP) 2004-361084
Aug. 23, 2005 (JP) 2005-241630
Oct. 4, 2005 (JP) 2005-291583

(51) Int. Cl. H01L 21/3105; H01L 21/677; B08B 3/04

(52) U.S. Cl. 134/21; 134/113; 134/99.1; 134/61; 134/63

(57) ABSTRACT

[Object] It is an object of the invention to provide a cleaning apparatus for cleaning a precision substrate capable of preventing a contamination factor from adhering again, to prevent a natural oxide film from being formed, and to prevent a water mark.

[Solving Means] In a cleaning apparatus 1, a substrate-to-be-cleaned 2 is disposed in a container 3, and an atmosphere component measuring device 4 which measures an atmosphere in the container 3, gas supply means 5 for controlling an atmosphere, and gas discharge means 6 and 7 are disposed in the cleaning apparatus 1, the cleaning apparatus 1 includes at least one the gas supply means 5 which equally supplies gas from a portion opposed to a surface-to-be-cleaned, gas supply means 21 for supplying gas to a rotating/holding mechanism comprising a cylindrical stationary shaft 16, a fluid bearing 17 and a rotation support member 18, gas discharge means 7 for discharging gas into a drainage mechanism, and gas supply means 31 for supplying gas for controlling an atmosphere when cleaning liquid is injected. The atmosphere component measuring device 4 which measures the atmosphere in the cleaning apparatus 1 can measure at any timing, and can detect one or more of a flammable component, a combustible component and a oxdizer component.

### TECHNICAL FIELD

The present invention relates to a cleaning apparatus for cleaning a precision substrate such as a semiconductor substrate, a liquid crystal glass substrate and a magnetic disk.

### BACKGROUND TECHNIQUE

In production of a precision substrate such as a semiconductor device, a liquid crystal display and a magnetic disk, in order to enhance the yield and reliability of the device, it is absolutely necessary to prevent the precision substrate from being contaminated. Therefore, a production step, a producing apparatus and a production environment have conventionally been improved to prevent the precision substrate from being contaminated in the producing process.

Even if the contamination preventing technique is improved, it is impossible to completely prevent the contamination in reality. Thus, a cleaning technique for removing contamination is important like the contamination preventing technique.

As the packing density of each device such as a semiconductor is increased and the precision thereof is enhanced, a contamination factor which becomes a problem becomes further strict, and not only heavy metal contamination but also particle contamination from environment and contamination from a producing apparatus become problems, and it is necessary to improve them.

In the cleaning technique required for the production step of a device such as a semiconductor in which the packing density and precision are further enhanced, control at anatomic or molecular level such as flattening technique of a precision substrate and prevention of natural oxide film formed on an outermost surface is required. For the contamination problem also, it is required to prevent the contamination at the atomic or molecular level such as moisture, an organic matter and other gas component existing in the production environment.

Thus, a producing apparatus of a device such as the semiconductor is disposed in a room called clean room where particles, temperature and moisture are controlled, and a precision substrate such as a semiconductor substrate, a liquid crystal glass substrate and a magnetic disk is exposed to environment in the clean room (see patent document 1 for example).

When an organic matter adhered to a gate insulative film which is called core of a semiconductor device, it is found that initial failure is increased, and in order to enhance the yield of the device, it is important to prevent an organic matter from adhering again.

In a film forming step or an etching step using special gas of inert gas for producing a semiconductor called dry process, in order to prevent the contamination on the atomic or molecular level such as moisture, organic matter and other gas component, it is proposed to develop or improve the producing technique for transferring a precision substrate to a next step in a clean environment. From such a point of view, an attempt is made to bring a cleaning apparatus having a clean environment into actual use.

To save cleaning liquid and to save an occupied area of the cleaning apparatus, development of a single substrate type precision substrate cleaning apparatus has been pursued in recent years. In many single substrate type cleaning apparatuses, a substrate-to-be-cleaned is held in its horizontal state, and rotating and holding means which can rotate is disposed (see patent document 2 for example).
[Patent Document 1] Japanese Patent Application Laid-open No. H9-64146 ((0024) and FIG. 1)
[Patent Document 2] Japanese Patent Application Laid-open No. 2001-15470 ((0022) and FIG. 1)

### DISCLOSURE OF THE INVENTION

### Problem to be Solved by the Invention

In the clean room environment of the patent document 1, although particles, temperature and moisture are controlled as described above, contamination at the atomic or molecular level such as moisture, an organic matter and other gas component is not completely removed. Thus, there is a problem that such a contamination factor adheres to a surface of the precision substrate. When a precision substrate is cleaned and contamination materials such as particles, metal and natural oxide film are removed from a surface of the precision substrate and then the precision substrate is left in a clean room, the surface thereof is oxidized by oxygen in the atmosphere and the oxide film is adversely formed. Therefore, in order to reliably prevent and remove the contamination and to maintain the clean degree on the surface of the precision substrate, the precision substrate should not be exposed to the atmosphere in the clean room unlike the conventional technique, and it is preferable that the precision substrate is transferred to a next step in a clean container in which inert gas with respect to the substrate is charged.

Main technical objects for transferring a precision substrate to a next step in a clean atmosphere are to supply/discharge inert gas, to enhance a throughput and to save cleaning liquid. In the supply/discharge of the inert gas, it is an object to supply and discharge single or mixed gas to and from a cleaning apparatus. The object to prevent and control the contamination at the atomic or molecular level such as moisture, an organic matter and other gas component existing in the atmosphere is not achieved. One reason thereof is that there is no optimal device for measuring the atmosphere in the cleaning apparatus.

Examples of generally commercially available devices for measuring a very small amount of gas component are a quadrupole type mass spectrometer, a diaphragm galvanic battery type oximeter and a zirconia type oximeter. A quadrupole type mass spectrometer is optimal as a device for analyzing a very small amount of gas component at ppm level. The quadrupole type mass spectrometer has such a measuring principle that voltage is applied to four electrodes (quadrupole columns) having a hyperboloid, gas molecular ion is emitted into the electrodes, and mass separation is carried out utilizing the fact that a ratio of the number of mass M of ion and valence Z of ion capable of passing through the quadrupole columnar by a potential difference between the electrodes. In order to ionize gas molecular ion and to introduce the same into a detector, it is necessary to maintain high vacuum in the device. The quadrupole type mass spectrometer is an optimal device for measuring gas component in the vacuum atmosphere, but since the cleaning liquid is used and discharged out, the quadrupole type mass spectrometer is not suitable for use in a cleaning apparatus under atmospheric atmosphere.

On the other hand, in the diaphragm galvanic battery type or zirconia type oximeter, it is necessary to select a type of the oximeter to be used in accordance with oxygen concentration to be measured. To measure oxygen of relatively high concentration about 21% (% level) included in the atmosphere, the diaphragm galvanic battery type oximeter is useful. To measure oxygen of low concentration of ppm level, the zirconia type oximeter is useful.

The diaphragm galvanic battery type oximeter comprises a noble metal electrode, a nonmetal electrode and an electrolytic solution, and oxygen in atmosphere to be measured is measured by exposing the noble metal electrode to the atmosphere to be measured. According to the diaphragm galvanic battery type oximeter, the oxygen concentration can be measured easily, oxygen can be measured in a cleaning apparatus of moisture concentration higher than atmosphere or normal case, but since the oxygen concentration measuring range is relatively high contamination, and since resolution is about 0.5%, it is difficult to precisely measure the oxygen concentration of extremely small level of ppm level.

The zirconia type oximeter receives and sends electrons of oxygen included in the atmosphere to be measured between zirconia ceramic electrodes to measure the oxygen in the atmosphere to be measured, and the oxygen concentration measuring range is ppm level. Since the zirconia type oximeter has high resolution, it is possible to precisely measure extremely small amount of oxygen concentration. However, since the zirconia type oximeter causes corrosion of the electrode, this oximeter is not suitable for measuring the oxygen in atmosphere where acid, alkaline, organic solvent component exists.

As described above, there is no device which is suitable for measuring atmosphere in the cleaning apparatus using various cleaning liquids, and the problem that contamination at the atomic or molecular level such as moisture, organic matter and other gas component existing in the atmosphere in the cleaning apparatus must be prevented or controlled has not yet been overcome.

In a cleaning step of the precision substrate or the cleaning apparatus, cleaning liquid such as the acid, alkaline, organic solvent or liquid such as superpure water is used for cleaning, moisture, organic matter, inorganic matter included in other cleaning liquid exist in the form of mist (vapor) in the atmosphere in the cleaning apparatus, and it is difficult to control the atmosphere in such a cleaning step.

If drying operation is not carried out completely after cleaning of the precision substrate, superpure water mist (vapor) or a drop of water remaining on the surface of the substrate vaporizes and contamination residue called water mark is generated thereby, and various problems such as re-contamination of a cleaned substrate and deterioration of roughness of the surface of the substrate are generated. It is reported that such natural oxide film and water mark deteriorate yield of each device such as a semiconductor and deteriorate reliability of the device, and in order to realize the high packing density, high precision, high reliability, and production of high yield required for each device in these days, it is absolutely necessary to prevent the natural oxide film and the water mark.

In drainage of cleaning liquid, development of techniques for separately draining different kinds of water and for collecting water has been pursued in view of environmental problem and energy save, but a drainage system in the cleaning apparatus is generally not shut off from outside air, and no countermeasure has been taken against the mix of outside air from the drainage system and the mix of vapor into cleaning liquid.

In the single substrate cleaning apparatus in which rotating/holding means as described in the patent document 2, most of rotation mechanisms are fixed to an outside portion of the cleaning apparatus, and outside air is mixed from a portion of the cleaning apparatus to which the rotation mechanism is connected and thus, there is a problem that it is difficult to maintain the atmosphere in the cleaning apparatus clean.

The present inventors researched very hard to solve these various problems and as a result, they found that formation of the natural oxide film is suppressed when a cleaned precision substrate is left in atmosphere component (clean dry air) from which moisture is removed, that oxygen which is oxidation species and moisture included in atmosphere interact with each other in the formation of the natural oxide film although detailed mechanism is not clear, that when a precision substrate is not exposed to the atmosphere in the and is transferred in a container, control of oxygen concentration and moisture concentration is important factor for controlling the charged inert gas, and that if the concentration of the oxygen which is oxidation species also in atmosphere where moisture exists is low in the process of formation of the natural oxide film, formation of the natural oxide film is suppressed.

The present invention is based on such findings, and it is an object of the invention to provide a cleaning apparatus for cleaning a precision substrate in which contamination factor at the atomic or molecular level such as moisture, organic matter and other gas component existing in the cleaning apparatus is controlled, and it is possible to prevent the contamination factor at the atomic or molecular level from again adhering after cleaning, prevent the natural oxidation formation, and to prevent the water mark.

Further, it is another object of the invention to provide a cleaning apparatus for cleaning a precision substrate in which concentration of oxygen existing in an atmosphere in a container where cleaning is carried out, especially atmosphere.

### Means for Solving Problem

A first aspect of the present invention provides a cleaning apparatus for cleaning a substrate-to-be-cleaned such as a semiconductor substrate, a liquid crystal glass substrate and a magnetic disk in a container, the cleaning apparatus comprising atmosphere control means for controlling an atmosphere in the container, and a atmosphere component measuring device for measuring the atmosphere in the container.

According to a second aspect of the invention, in the cleaning apparatus of the first aspect, the atmosphere control means comprises gas supply means for supplying gas into the container, and gas discharge means for discharging the gas from the container.

According to a third aspect of the invention, in the cleaning apparatus of the first aspect, the atmosphere in the container is measured at any timing.

According to a fourth aspect of the invention, in the cleaning apparatus of the first aspect, an oxygen concentration is controlled by the atmosphere control means.

According to a fifth aspect of the invention, in the cleaning apparatus of the first aspect, the atmosphere component measuring device detects at least one of a flammable component, a combustible component and a oxdizer component.

According to a sixth aspect of the invention, in the cleaning apparatus of the fifth aspect, the oxdizer component is oxygen.

According to a seventh aspect of the invention, the cleaning apparatus of the second aspect further comprises first gas supply means for equally supplying gas from a portion of the substrate-to-be-cleaned opposed to a surface-to-be-cleaned as the gas supply means.

According to an eighth aspect of the invention, the cleaning apparatus of the seventh aspect further comprises a rotating/holding mechanism which holes the substrate-to-be-cleaned in its horizontal state and rotates the substrate-to-be-cleaned, and second gas supply means for supplying gas to the rotating/holding mechanism as the gas supply means.

According to a ninth aspect of the invention, the cleaning apparatus of the seventh aspect further comprises a cleaning liquid injection mechanism for injecting cleaning liquid toward the surface-to-be-cleaned of the substrate-to-be-cleaned, and third gas supply means for supplying gas to control an atmosphere in the cleaning liquid injection mechanism as the gas supply means.

According to a tenth aspect of the invention, the cleaning apparatus of the first aspect further comprises a drainage mechanism for draining cleaning waste liquid to desired one of an acid/alkali/organic drainage system and a general drainage system in a classified manner, wherein gas is discharged from the drainage mechanism.

According to an eleventh aspect of the invention, in the cleaning apparatus of the tenth aspect, the drainage mechanism includes a plurality of cup-like induction walls arranged concentrically, wherein a drainage passage and a gas flow passage are formed by gaps between the cup-like induction walls, the gas flow passage includes a first passage having a great flow passage cross section formed between the cup-like induction walls, and a second passage having a small flow passage cross section connected to a downstream side of the first passage, and the flow passage cross section is designed such that a flow velocity of gas passing through the second passage becomes the maximum.

According to a twelfth aspect of the invention, in the cleaning apparatus of the eighth aspect, the rotating/holding mechanism includes a table which is disposed in the container and which holds the substrate-to-be-cleaned, a rotation shaft for rotating the table, and a fluid bearing for holding the rotation shaft, a pressure in the container is set higher than the pressure of the fluid bearing, and the pressure of the fluid bearing is set higher than atmospheric pressure.

According to a thirteenth aspect of the invention, in the cleaning apparatus of the tenth aspect, the drainage mechanism includes a drive shaft for independently vertically moving a plurality of cup-like induction walls, a stationary flange and a movable flange are disposed such as to surround the drive shaft, and bellows are disposed between the stationary flange and the movable flange.

According to a fourteenth aspect of the invention, in the cleaning apparatus of the first aspect, a pressure of an atmosphere in the container is reduced.

According to a fifteenth aspect of the invention, in the cleaning apparatus of the first aspect, a dew point temperature of water in an atmosphere in the container can be controlled.

According to a sixteenth aspect of the invention, the cleaning apparatus of the first aspect further comprises a rotating/holding mechanism which holds the substrate-to-be-cleaned in its horizontal state and rotates the substrate-to-be-cleaned, wherein the rotating/holding mechanism includes a table for holding the substrate-to-be-cleaned, a gas discharge hole for supplying inert gas is formed between the substrate-to-be-cleaned and the table, the inert gas to be supplied from the gas discharge hole is discharged from an outer periphery of the substrate-to-be-cleaned, and a ring projection having an inner diameter smaller than the outer periphery of the substrate-to-be-cleaned is provided on the table.

According to a seventeenth aspect of the invention, in the cleaning apparatus of the sixteenth aspect, the gas discharge hole has an injection passage having a diameter smaller than that of an upstream side passage through which the inert gas is supplied.

A cleaning system according to an eighteenth aspect of the invention using the cleaning apparatus according to any one of first to seventeenth aspects comprises a transfer device having a transfer mechanism which transfers the substrate-to-be-cleaned into and out from the cleaning apparatus, a cut-off mechanism for cutting off an atmosphere in the transfer device and an atmosphere in the cleaning apparatus from each other, and atmosphere control means for controlling the atmosphere in the transfer device.

According to a nineteenth aspect of the invention, the cleaning system of the eighteenth aspect, the atmosphere control means comprises gas supply means for supplying gas into the transfer device, and gas discharge means for discharging out the gas from the transfer device.

According to a twentieth aspect of the invention, in the cleaning system of the eighteenth aspect, a connecting device to which a special case is freely detachably attached is connected to the transfer device through a cut-off mechanism for cutting off an atmosphere in the transfer device, and the special case transfers and stores the substrate-to-be-cleaned.

According to a twenty-first aspect of the invention, in the cleaning system of the eighteenth aspect, a dryer for drying the substrate-to-be-cleaned is connected to the transfer device through a cut-off mechanism for cutting off an atmosphere in the transfer device, and the dryer includes atmosphere control means for controlling an atmosphere in the dryer.

According to a twenty-second aspect of the invention, in the cleaning system of the twenty-first aspect, the atmosphere control means comprises gas supply means for supplying gas into the dryer, and gas discharge means for discharging the gas from the dryer.

According to a twenty-third aspect of the invention, in the cleaning system of the twenty-first aspect, one or more devices which carry out a step before or/and after a cleaning operation of the substrate-to-be-cleaned is connected to the transfer device through a cut-off mechanism for cutting off an atmosphere in the transfer device.

According to a twenty-fourth aspect of the invention, in a cleaning system using the cleaning apparatus of the second aspect, the gas supply means is connected to each one of gas supply openings of the plurality of cleaning apparatuses through dampers which can freely be controlled, and the gas discharge means is connected to each one of gas discharge openings of the plurality of cleaning apparatuses through the dampers.

A cleaning method for cleaning a substrate-to-be-cleaned according to a twenty-fifth aspect of the invention using the cleaning apparatus according to any one of the first to seventeenth aspects, comprises a step for evacuating the container, a step for stopping the evacuating step when a pressure in the container is reduced to a desired level, a step for introducing inert gas into the container and discharging gas in the container when the pressure in the container is increased to a predetermined pressure level, a step for measuring the atmosphere in the container and controlling the atmosphere to a predetermined atmosphere, a step for rotating the substrate-to-be-cleaned and injecting a predetermined cleaning liquid to the substrate-to-be-cleaned while flowing inert gas into the container, and a step for draining the cleaning liquid after cleaning to a plurality of drainage systems in a classified manner.

### EFFECT OF THE INVENTION

According to the present invention, gas supply means for controlling an atmosphere in a cleaning apparatus such as a semiconductor device, a liquid crystal display and a magnetic disk, gas discharge means and an atmosphere component measuring device are included. With this, it is possible to control a contamination factor at the atomic or molecular level such as moisture, organic matter and other gas component existing in a cleaning apparatus atmosphere, it is possible to prevent a contamination factor from adhering again at the atomic or molecular level after cleaning, to prevent a natural oxide film from being formed and to prevent a water mark. It is possible to provide a cleaning apparatus capable of cleaning a precision substrate with high quality and high yield in a clean atmosphere, and capable of maintaining a clean degree of the substrate-to-be-cleaned.

It is possible to freely measure an atmosphere component in the cleaning apparatus. With this, a high quality precision substrate cleaning step is established, quality of the cleaning operation of the precision substrate can be secured, and it is possible to enhance the yield of production of devices such as semiconductors.

The gas supply means and gas discharge means can control the oxygen concentration. With this, it is possible to prevent a natural oxide film from being formed, and to maintain a clean atmosphere in the cleaning apparatus.

The atmosphere component measuring device capable of detecting the flammable component, the combustible component and the oxdizer component is disposed in the cleaning apparatus, and the combustible component can be measured if required. Therefore, it is possible to safely clean the precision substrate with high quality in the clean atmosphere, and quality of the cleaning operation of the precision substrate can be secured. Thus, it is possible to enhance the yield of the production of devices such as the semiconductors.

In the atmosphere component measuring device for securing the safety, since it is possible to detect the concentration of oxygen which is the oxdizer component, it is possible to prevent a natural oxide film from being formed safely in the clean atmosphere.

Since it is possible to efficiently maintain a clean atmosphere in the cleaning apparatus, gas does not stay in the cleaning apparatus almost at all, a driving portion of the cleaning liquid injection mechanism can be disposed on a projection in the cleaning device, the cleaning apparatus can be made compact, the cross-sectional area in the device can be saved, the total flow rate of gas required for controlling the atmosphere is reduced, and it is possible to realize a cleaning apparatus capable of solving an environmental problem, saving energy, and reducing an occupied area.

Since it is possible to dry the substrate-to-be-cleaned while maintaining the clean degree of the substrate-to-be-cleaned, it is possible to prevent a water mark, and to reliably produce devices such as semiconductors with high yield.

The transfer device, the dryer, the connecting device and devices for carrying out steps before and after the cleaning operation whose atmospheres are controlled are disposed. With this, it is possible to control a contamination factor at the atomic or molecular level such as moisture, organic matter and other gas component, and it is possible to prevent a contamination factor at the atomic or molecular level from adhering again after the cleaning operation, to prevent a natural oxide film from being formed, and to prevent the water mark, and it is possible to realize high quality, high yield and high throughput of production of devices such as semiconductors.

Therefore, the cleaning apparatus of the present invention can largely contribute to production quality and production cost in producing and manufacturing a semiconductor product, an electronic part and a home electric appliance such as a semiconductor device, a liquid crystal display and a magnetic disk.

### BRIEF DESCRIPTION OF THE DRAWINGS

FIG. 1 is a sectional side view of a cleaning apparatus according to a first embodiment of the present invention;

FIG. 2 is an enlarged sectional side view of a water distribution system portion of the cleaning apparatus of the first embodiment of the invention;

FIG. 3 is a sectional side view of a induction wall vertically driving portion of the cleaning apparatus of the first embodiment of the invention;

FIG. 4 is a cleaning time dependency diagram of an oxygen concentration in the cleaning apparatus when the cleaning apparatus of the invention is not used;

FIG. 5 is a cleaning time dependency diagram of an oxygen concentration in the cleaning apparatus when the cleaning apparatus of the invention is used;

FIG. 6 is a plan view of a cleaning apparatus according to a second embodiment of the invention;

FIG. 7 is a conceptional diagram showing a gas supply discharge structure of a cleaning apparatus according to a third embodiment of the invention;

FIG. 8 is a sectional side view of a substrate-to-be-cleaned support portion of a cleaning apparatus according to a fourth embodiment of the invention; and

FIG. 9 is a sectional side view of a substrate-to-be-cleaned support portion of a cleaning apparatus according to a fifth embodiment of the invention.

### EXPLANATION OF SYMBOLS

1 cleaning apparatus
2 substrate-to-be-cleaned
3 container
4 atmosphere component measuring device
5 gas supply means
6 gas discharge means
7 gas discharge means
8 valve
9 vacuum pump
10 pressure measuring device
11 pressure-reducing valve
12 mass flow controller
13, 14 valve
15 shower plate
16 cylindrical stationary shaft
17 fluid bearing
18 rotation support member
19 table
20 drive motor
21 gas supply means
22, 23, 59 drainage opening
24, 25, 60 induction wall
26, 27, 58 vertically driving motor
28, 29, 30 discharge opening
31 gas supply means
32 cleaning liquid supply pipe
33 cleaning liquid supply pipe
34 rotation support portion
35 cleaning liquid injection arm
36 upper nozzle
37 upper nozzle
38 drive motor
39 transfer mechanism
40 transfer device
41, 51, 52, 53 cut-off mechanism
42 gas supply means
43 gas discharge means
44 special case
45 connecting device
46 gas supply means
47 gas discharge means
48 dryer
49 device which carries out steps before and after cleaning operation
55, 56, 57 drive shaft
61, 64 stationary flange
62, 65 movable flange
63, 66 bellows
68 cleaning chamber
70 drainage passage
701 lateral passage
702 vertical passage
72, 73, 74, 75, 76, 77 chamber
80, 82, 84, 86, 88, 90 supply-side damper
81, 83, 85, 87, 89, 91 discharge-side damper
93 chuck
94 nozzle member
95 gas discharge hole
96 pawls
97 ring projection
98 inert gas passage
99 outer ring projection
100 inert gas
101, 102 inert gas passage
111 substrate-to-be-cleaned holding stage
112 gas discharge portion
113 gas introducing opening
114 gas chamber
115 gas discharge hole

### BEST MODE FOR CARRYING OUT THE INVENTION

A first aspect of the present invention provides a cleaning apparatus comprising atmosphere control means for controlling an atmosphere in the container, and a atmosphere component measuring device for measuring the atmosphere in the container. With this aspect, it is possible to maintain the atmosphere in the clean cleaning apparatus in which a contamination component at the atomic or molecular level such as moisture, organic matter and other gas component is controlled.

According to a second aspect of the invention, in the cleaning apparatus of the first aspect, the atmosphere control means comprises gas supply means for supplying gas into the container, and gas discharge means for discharging the gas from the container. With this aspect, it is possible to control the pressure and the concentration of gas in the container by supplying and discharging the gas.

According to a third aspect of the invention, in the cleaning apparatus of the first aspect, the atmosphere in the container is measured at any timing. With this aspect, since the atmosphere component in the container is measured as required, it is possible to clean the precision substrate with high quality.

According to a fourth aspect of the invention, in the cleaning apparatus of the first aspect, an oxygen concentration is controlled by the atmosphere control means. With this aspect, it is possible to reliably control the oxygen concentration which largely influences the formation of a natural oxide film. Thus, it is possible to prevent the natural oxide film from being formed and to maintain the clean atmosphere.

According to a fifth aspect of the invention, in the cleaning apparatus of the first aspect, the atmosphere component measuring device detects at least one of a flammable component, a combustible component and a oxdizer component. With this aspect, since it is possible to reliably detect the flammable component, the combustible component and the oxdizer component included in the cleaning liquid, it is possible to prevent a fire and an explosion of the cleaning apparatus, and to safely clean the precision substrate in the clean atmosphere.

According to a sixth aspect of the invention, in the cleaning apparatus of the fifth aspect, the oxdizer component is oxygen. With this aspect, since it is possible to reliably detect oxygen which is the oxdizer component, it is possible to safely clean a precision substrate with high quality while preventing a natural oxide film from being formed in the clean atmosphere.

According to a seventh aspect of the invention, the cleaning apparatus of the second aspect further comprises first gas supply means for equally supplying gas from a portion of the substrate-to-be-cleaned opposed to a surface-to-be-cleaned as the gas supply means. With this aspect, the atmosphere of the surface-to-be-cleaned of the substrate-to-be-cleaned can be equalized.

According to an eighth aspect of the invention, the cleaning apparatus of the seventh aspect further comprises a rotating/holding mechanism which holes the substrate-to-be-cleaned in its horizontal state and rotates the substrate-to-be-cleaned, and second gas supply means for supplying gas to the rotating/holding mechanism as the gas supply means. With this aspect, it is possible to prevent gas from staying near the rotating/holding mechanism, and to control the atmosphere in the rotating/holding mechanism.

According to a ninth aspect of the invention, the cleaning apparatus of the seventh aspect further comprises a cleaning liquid injection mechanism for injecting cleaning liquid toward the surface-to-be-cleaned of the substrate-to-be-cleaned, and third gas supply means for supplying gas to control an atmosphere in the cleaning liquid injection mechanism as the gas supply means. With this aspect, it is possible to prevent gas from staying near the rotating/holding mechanism, and to control the atmosphere in the cleaning liquid injection mechanism.

According to a tenth aspect of the invention, the cleaning apparatus of the first aspect further comprises a drainage mechanism for draining cleaning waste liquid to desired one of an acid/alkali/organic drainage system and a general drainage system in a classified manner, wherein gas is discharged from the drainage mechanism. With this aspect, it is possible to equalize the atmosphere in the surface-to-be-cleaned of the substrate-to-be-cleaned.

According to an eleventh aspect of the invention, in the cleaning apparatus of the tenth aspect, the drainage mechanism includes a plurality of cup-like induction walls arranged concentrically, wherein a drainage passage and a gas flow passage are formed by gaps between the cup-like induction walls, the gas flow passage includes a first passage having a great flow passage cross section formed between the cup-like induction walls, and a second passage having a small flow passage cross section connected to a downstream side of the first passage, and the flow passage cross section is designed such that a flow velocity of gas passing through the second passage becomes the maximum. With this aspect, it is possible to prevent an atmosphere or a discharged gas from reversely flowing from downstream into the drainage flow passage.

According to a twelfth aspect of the invention, in the cleaning apparatus of the eighth aspect, the rotating/holding mechanism includes a table which is disposed in the container and which holds the substrate-to-be-cleaned, a rotation shaft for rotating the table, and a fluid bearing for holding the rotation shaft, a pressure in the container is set higher than the pressure of the fluid bearing, and the pressure of the fluid bearing is set higher than atmospheric pressure. With this aspect, the fluid bearing does not generate dust corresponding to high vacuum, and it is possible to prevent particle and outside air from the fluid bearing from being mixed and to seal the fluid bearing.

According to a thirteenth aspect of the invention, in the cleaning apparatus of the tenth aspect, the drainage mechanism includes a drive shaft for independently vertically moving a plurality of cup-like induction walls, a stationary flange and a movable flange are disposed such as to surround the drive shaft, and bellows are disposed between the stationary flange and the movable flange. With this aspect, an atmosphere entering from peripheries of upper and lower drive shaft is captured in a space surrounded by the stationary flange, the movable flange and the bellow, and it is possible to prevent the atmosphere from entering the cleaning apparatus.

According to a fourteenth aspect of the invention, in the cleaning apparatus of the first aspect, a pressure of an atmosphere in the container is reduced. With this aspect, since it is possible to prevent a water mark from being formed after cleaning, it is possible to prevent a substrate from being oxidized, to prevent a clean substrate from being contaminated, and to prevent surface roughness of the substrate from being deteriorated.

According to a fifteenth aspect of the invention, in the cleaning apparatus of the first aspect, a dew point temperature of water in an atmosphere in the container can be controlled. With this aspect, since it is possible to prevent a water mark from being formed after cleaning, it is possible to prevent a substrate from being oxidized, to prevent a clean substrate from being contaminated, and to prevent surface roughness of the substrate from being deteriorated.

According to a sixteenth aspect of the invention, in the cleaning apparatus of the first aspect, a ring projection having an inner diameter smaller than the outer periphery of the substrate-to-be-cleaned is provided on the table. With this aspect, since the ring projection is disposed, the flowing around position of the cleaning liquid toward the back surface of the substrate-to-be-cleaned can be controlled by the number of revolutions of the substrate-to-be-cleaned and the flow rate of inert gas to be supplied between the table and the substrate-to-be-cleaned, and it is possible to equally clean the back surface of the substrate-to-be-cleaned and to prevent the back surface of the substrate-to-be-cleaned from being contaminated again.

According to a seventeenth aspect of the invention, in the cleaning apparatus of the sixteenth aspect, the gas discharge hole has an injection passage having a diameter smaller than that of an upstream side passage through which the inert gas is supplied. With this aspect, even if the substrate-to-be-cleaned is damaged during cleaning of the substrate-to-be-cleaned, it is possible to prevent the cleaning liquid from entering the discharge hold for inert gas.

A cleaning system using the cleaning apparatus comprises a transfer device having a transfer mechanism which transfers the substrate-to-be-cleaned into and out from the cleaning apparatus, a cut-off mechanism for cutting off an atmosphere in the transfer device and an atmosphere in the cleaning apparatus from each other, and atmosphere control means for controlling the atmosphere in the transfer device. With this aspect, when the substrate-to-be-cleaned is brought into and out from the cleaning apparatus, it is possible to prevent a contamination factor from adhering again to the substrate-to-be-cleaned. Thus, the substrate-to-be-cleaned can be brought into and out from the cleaning apparatus while keeping the clean degree.

According to a nineteenth aspect of the invention, the cleaning system of the eighteenth aspect, the atmosphere control means comprises gas supply means for supplying gas into the transfer device, and gas discharge means for discharging out the gas from the transfer device. With this aspect, the pressure, the concentration and the temperature of gas in the transfer device can be controlled by supplying and discharging the gas.

According to a twentieth aspect of the invention, in the cleaning system of the eighteenth aspect, a connecting device to which a special case is freely detachably attached is connected to the transfer device through a cut-off mechanism for cutting off an atmosphere in the transfer device, and the special case transfers and stores the substrate-to-be-cleaned. With this aspect, the substrate-to-be-cleaned can be transferred to a device of a next step or stored while keeping the clean degree.

According to a twenty-first aspect of the invention, in the cleaning system of the eighteenth aspect, a dryer for drying the substrate-to-be-cleaned is connected to the transfer device through a cut-off mechanism for cutting off an atmosphere in the transfer device. With this aspect, it is possible to dry mist (vapor) superpure water or residue remaining the outermost surface of the substrate while keeping the clean degree of the substrate-to-be-cleaned. Thus, it is possible to prevent a local natural oxide film from being formed and to prevent a water mark from being formed.

According to a twenty-second aspect of the invention, in the cleaning system of the twenty-first aspect, the atmosphere control means comprises gas supply means for supplying gas into the dryer, and gas discharge means for discharging the gas from the dryer. With this aspect, the pressure, the concentration and the temperature of gas in the transfer device can be controlled by supplying and discharging the gas.

According to a twenty-third aspect of the invention, in the cleaning system of the twenty-first aspect, one or more devices which carry out a step before or/and after a cleaning operation of the substrate-to-be-cleaned is connected to the transfer device through a cut-off mechanism for cutting off an atmosphere in the transfer device. With this aspect, it is possible to carry out steps before and after the cleaning while maintaining the clean degree of the substrate-to-be-cleaned, high quality film forming step and etching step can be carried out, and it is possible to enhance the quality, throughput and yield of devices such as the semiconductors.

According to a twenty-fourth aspect of the invention, in a cleaning system using the cleaning apparatus of the second aspect, the gas supply means is connected to each one of gas supply openings of the plurality of cleaning apparatuses through dampers which can freely be controlled, and the gas discharge means is connected to each one of gas discharge openings of the plurality of cleaning apparatuses through the dampers. With this aspect, by opening and closing the damper of each cleaning apparatus, the plurality of cleaning apparatuses can be operated independently from one another. Thus, a substrate-to-be-cleaned of any one of the cleaning apparatuses can be exchanged or transferred without influencing other cleaning apparatuses.

A cleaning method for cleaning a substrate-to-be-cleaned according to a twenty-fifth aspect of the invention using the cleaning apparatus according to any one of the first to seventeenth aspects, comprises a step for evacuating the container, a step for stopping the evacuating step when a pressure in the container is reduced to a desired level, a step for introducing inert gas into the container and discharging gas in the container when the pressure in the container is increased to a predetermined pressure level, a step for measuring the atmosphere in the container and controlling the atmosphere to a predetermined atmosphere, a step for rotating the substrate-to-be-cleaned and injecting a predetermined cleaning liquid to the substrate-to-be-cleaned while flowing inert gas into the container, and a step for draining the cleaning liquid after cleaning to a plurality of drainage systems in a classified manner. With this aspect, it is possible to clean cleanly while controlling contamination component at the atomic or molecular level such as moisture, organic matter and other gas component.

### FIRST EMBODIMENT

An embodiment of the present invention will be explained in detail together with the drawings.

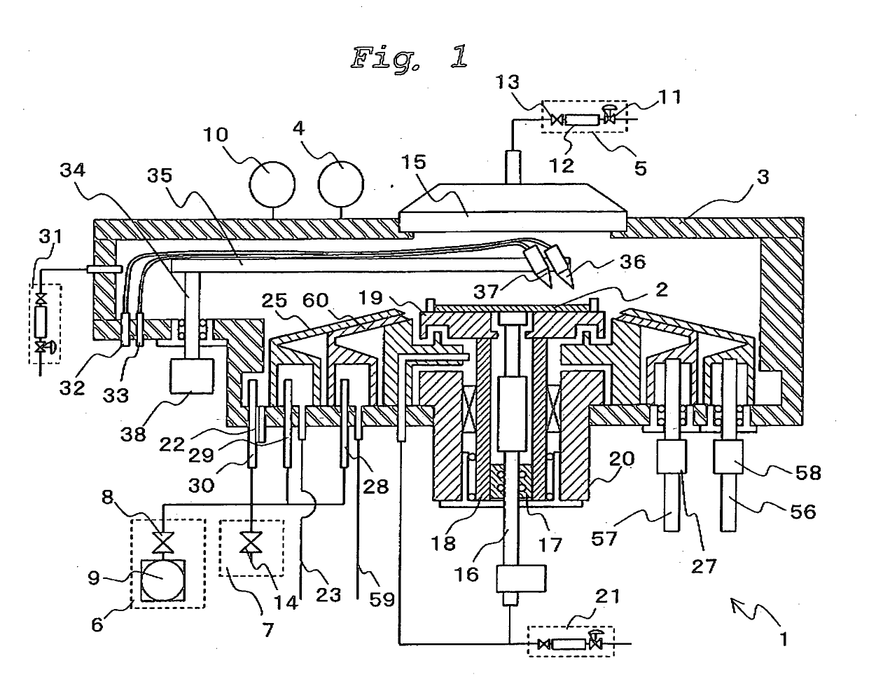

FIG. 1 is a sectional view showing one example of a structure of a cleaning apparatus according to the embodiment of the present invention. A cleaning operation in the invention includes cleaning operations comprising several steps using a cleaning liquid such as acid, alkaline and organic solvent, such a cleaning liquid to which a surface-active agent is added, a cleaning liquid or ozone water in which an extremely small amount of gas called function water is solved in superpure water, superpure water or a combination thereof.

The cleaning apparatus 1 has a substrate-to-be-cleaned 2 disposed in a container 3. An atmosphere component measuring device 4 for cutting off from outside air and measures an atmosphere in the container 3, gas supply means 5 for controlling the atmosphere and gas discharge means 6 and 7 are disposed. The atmosphere control means comprises the gas supply means 5 and the gas discharge means 6 and 7, and controls the atmosphere in the container 3. The atmosphere in the container 3 may be pressure, temperature or concentration. Preferable control of the atmosphere in the container 3 is the control of oxygen concentration and an oximeter is preferable as atmosphere component measuring device 4, because oxygen which is oxidation species and moisture included in the atmosphere interact with each other for forming the above-described natural oxide film formation, because control of the oxygen concentration and moisture concentration is one of important factor for controlling inert gas to be charged when a precision substrate is transferred in the container without being exposed to the atmosphere in a clean room, and because the formation of the natural oxide film is suppressed if the oxygen concentration which is the oxidation species is low even at the atmosphere where moisture exists in the process of formation of the natural oxide film.

The gas supply means 5 comprises a pressure-reducing valve 11, a mass flow controller 12 and a valve 13. The gas supply means 5 supplies inert gas into the container 3. The gas supply means 5 is supply means of single gas. Nitrogen and argon are preferable as the inert gas, but kinds of gas may freely be selected in accordance with kinds of the substrate-to-be-cleaned 2 or cleaning purpose, and mixed gas may be used instead of the single gas. The gas supply means 5 is disposed on an upper surface of the cleaning apparatus 1 at a position opposed to a surface-to-be-cleaned of the substrate-to-be-cleaned 2 so that gas is equally supplied from the position opposed to the surface-to-be-cleaned of the substrate-to-be-cleaned 2 and more particularly, a shower plate 15 having 100 holes having inner diameter of 0.5 mm is disposed. The size of the shower plate 15 is substantially equal to that of the substrate-to-be-cleaned 2. The shape, the inner diameter and the number of holes of the shower plate 15 may be determined so as to realize equal gas supply by means of the size and shape of the substrate-to-be-cleaned 2, and the shower plate 15 is not limited to the above-described structure.

Although the combination of the general gas flow rate control system comprising the pressure-reducing valve 11, the mass flow controller 12 and the valve 13 has been explained as the gas supply means 5, a flow rate control by means of pressure control can sufficiently be used, a member constituting the gas flow rate control system is not limited to the above-described combination, and it is preferable to delete a gas residence portion from a supply pipe.

The gas discharge means 6 including a valve 8 and a vacuum pump 9 provided downstream from the valve 8 is a gas discharge system for evacuation discharging. The gas discharge means 7 including a valve 14 is a gas discharge system for general discharging. The discharge discharge system can be switched by the valve 8 and a valve 14. It is preferable that the gas residence portion is deleted from the discharge pipes of the gas discharge means 6 and 7 to efficiently replace gas. It is preferable that that discharge opening is disposed along a concentric circle to produce equal flow of fluid, and two discharge openings may be formed separately for evacuation discharging and general discharging.

The atmosphere component measuring device 4 measures the atmosphere component in the container 3, and a pressure measuring device 10 measured the pressure in the container 3.

A cylindrical stationary shaft 16 is inserted into the container 3 from a substantially central portion of a lower portion of the container 3. A rotation support member 18 is supported by the cylindrical stationary shaft 16 through a fluid bearing 17 such that the rotation support member 18 can rotate around the cylindrical stationary shaft 16. A table 19 which horizontally holds the substrate-to-be-cleaned 2 is connected to an upper end of the rotation support member 18, and a drive motor 20 is disposed on a lower end of the rotation support member 18 such as to surround the lower end. If the rotation support member 18 is rotated by the drive motor 20, the substrate-to-be-cleaned 2 can rotate through the table 19. The cylindrical stationary shaft 16, the fluid bearing 17, the rotation support member 18, the table 19 and the drive motor 20 correspond to the rotating/holding means of the present invention.

Gas supply means 21 for supplying inert gas is connected to the rotating/holding means. The gas supply means 21 prevents outside air from the rotating/holding means from being mixed by the inert gas supplied from the gas supply means 21. Like the gas supply means 5, the gas supply means 21 comprises a combination for controlling a general gas flow rate having a pressure-reducing valve, a valve and a mass flow controller, but a flow rate control by means of pressure control can sufficiently be used. Concerning the gas supply pipe, it is preferable to delete a gas residence portion. In the example shown in FIG. 1, the gas supply opening supplies to two locations where the cylindrical stationary shaft 16 and the fluid bearing 17 are sealed and fixed, but these locations are not limited to those.

Gas in the rotating/holding means is discharged out through both the gas discharge means 6 and 7. With this, the number of machining steps of the container 3 is reduced, the producing cost is reduced but the technique is not limited to this, gas supply means suitable for the number of gas supply systems may be disposed, and gas discharge means which is special for the gas supply means 21 which is disposed in the rotating/holding means may be disposed. Although the rotation support member 18 is rotated directly by the drive motor 20 as means for rotating the substrate, the invention is not limited to this, other structures may be employed. For example, a pulley may be connected to the rotation support member 18, the pulley may be rotated as a timing pulley to be driven, and the substrate may be rotated.

In the rotation mechanism disposed outside of the apparatus as in this embodiment, a rotation support member is disposed on a stationary shaft through a fluid bearing such as a general bearing, and it is not easy to prevent particle or outside air from being mixed. Hence, if a rotation shaft sealing type fluid bearing generating no dust which can be used in high vacuum atmosphere by a combination of a strong magnet and a magnetic fluid called magnetic seal unit used for a vacuum apparatus is employed as the fluid bearing 17, it is possible to seal a rotation shaft fluid bearing which prevents particle or outside air from being mixed.

In this case, there is an adverse possibility that if the pressure in the container 3 of the cleaning apparatus 1 is smaller than the atmosphere, the atmosphere component disperses the magnetic fluid and may enter the cleaning apparatus 1, and this may form a natural oxide film. To prevent this, the pressures should be adjusted such as to establish a relation V1>V2>V3 wherein the pressure in the container 3 is V1, the pressure of the fluid bearing 17 is V2 and the atmospheric pressure is V3. Alternatively, an auxiliary chamber may be provided at a position in the fluid bearing 17 on the side of the atmosphere, and the pressure in the auxiliary chamber may be set smaller than the pressure in the chamber of the cleaning apparatus 1.

A magnetic material used for the magnetic seal unit generally does not have excellent corrosion-resistant properties, if the magnetic seal unit is employed for sealing the fluid bearing of the rotation shaft, it is preferable that separate gas supply means and gas discharge means are provided for protecting the magnetic seal unit from the cleaning apparatus atmosphere where cleaning liquid vapor (mist) such as acid and alkali exists.

Next, a drainage mechanism capable of draining water to a desired drainage system in a classified manner such as an acid/alkali/organic drainage system of the present invention and a general drainage system will be explained.

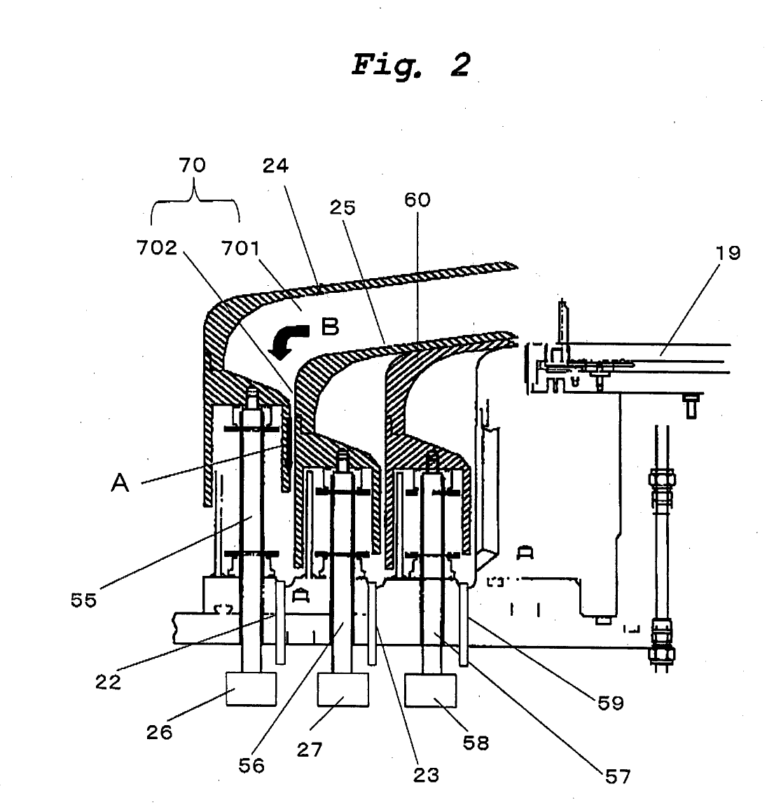

FIG. 2 is an enlarged view of the drainage mechanism shown in FIG. 1. In FIG. 2, the same members as those shown in FIG. 1 are designated with the same symbols and explanation thereof will be omitted. As shown in FIGS. 1 and 2, acid/alkali/organic drainage openings 22 and 23 and a drainage opening 59 of a general drainage system are provided below the container 3. To induce desired cleaning waste liquid is induced to drainage openings 22 and 23 into the container 3, a plurality of cup-like induction walls 24 and 25 which are disposed concentrically and a cup-like induction wall 60 for inducing cleaning water to the drainage opening 59 are disposed in the container 3. The induction walls 24, 25 and 60 are disposed in a state where cup shapes whose bottoms are opened are inverted, and the table 19 is disposed in the opened bottom. By forming gaps between the induction walls 24, 25 and 60, a drainage passage and a gas discharge passage are formed.

Vertically driving motors 26, 27 and 58 for vertically moving the induction walls 24, 25 and 60 and drive shafts 55, 56 and 57 are disposed on lower portions of the induction walls 24, 25 and 60. If the drive shafts 55, 56 and 57 are vertically moved by the vertically driving motors 26, 27 and 58 to vertically move the induction walls 24, 25 and 60, desired waste liquids can be induced to desired drainage systems, respectively. The drainage openings 22, 23 and 59, the induction walls 24, 25 and 60, the vertically driving motors 26, 27 and 58 and the drive shafts 55, 56 and 57 correspond to the drainage mechanism of the present invention. In this embodiment, the discharge openings 28, 29 and 30 and the drainage openings 22, 23 and 59 are provided in the respective drainage system sections such that they have different height so that waste liquid is not mixed into the discharge system, thereby preventing outside air from the drainage system from being mixed. The discharge openings 28, 29 and 30 are connected to the gas discharge means 6 (vacuum discharge) and the gas discharge means 7 (normal discharge), and the switching between the vacuum discharge and the normal discharge is carried out using the valves 8 and 14. In stead of using the gas discharge means 6 and 7, it is also possible to separately disposed gas discharge means only for preventing outside air from the drainage system from being mixed.

As shown in FIG. 2, cleaning liquid is drained into the drainage opening 22 from the gap between the induction walls 24 and 25. At that time, if the gap between the induction walls 24 and 25 is great, the cross-sectional area of the cleaning liquid passage is increased and water can easily be discharged. If this gap is large, there is an adverse possibility that atmosphere or discharged gas passes through the gap and reversely flows into the container 3 of the cleaning apparatus 1. Hence, in this embodiment, a gas passage 70 formed between the induction wall 24 and the induction wall 25 comprises an upstream side lateral passage 701 which gently extends from the table 19 and which has a great flow passage cross section, and a downstream side vertical passage 702 which is abruptly downwardly bent from the lateral passage 701 and which has a small flow passage cross section. The vertical passage 702 has a ring-like shape formed by a gap formed between a vertical portion of the cup-like induction wall 24 and a vertical portion of the cup-like induction wall 25. Therefore, the inert gas passage 70 is narrowed at the vertical passage 702, and its flow passage cross section becomes smaller than that of the lateral passage 701.

Generally, in the gas flow passage such as the inert gas passage 70, if the cross-sectional area of the gas passage is great, the gas flow velocity is small, and of the cross-sectional area is small, the gas flow velocity is high. Therefore, the gas flow velocity at the narrowed vertical passage 702 of the inert gas passage 70 is higher than that of the upstream side lateral passage 701. The flow passage cross section is designed such that the flow velocity of gas flow A flowing to the vertical passage 702 at that time becomes maximum as compared with the gas flow velocity in the upstream side lateral passage 701 and the gas flow velocity downstream from the vertical passage 702. With this, air from the cup-like induction wall is efficiently discharged and it is possible to prevent the atmosphere or discharged gas from reversely flowing into the vertical passage 702 from the downstream. This is carried out in the following manner.

Generally, when the flow passage cross-sectional area is constant, the gas flow becomes laminar flow if the velocity is low, and if the velocity becomes high, the flow is changed from the intermediate flow to the turbulent flow. As indices of the turbulent flow and laminar flow, Reynolds number is known. If the flow passage cross section is designed such that the gas flow A of the lateral passage 701 and the gas flow B of the vertical passage 702 become laminar flows from the intermediate flows and the flow velocity of the gas flow B of the vertical passage 702 becomes maximum, it is possible to prevent the atmosphere or discharged gas from reversely flowing from downstream of the vertical passage 702.

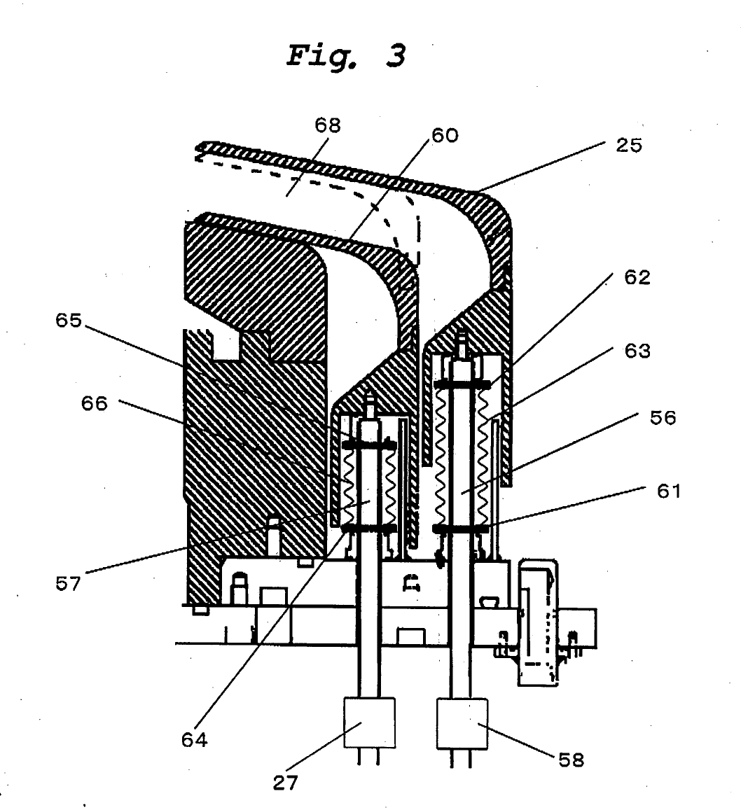

The fluid bearing 17 of the magnetic seal unit type is effective as the sealing means of the drive portion in rotation and drive as described above, but as the vertical driving by the vertically driving motors 26, 27 and 58 and the drive shafts 55, 56 and 57, sealing means for sealing the periphery using a spring-like thin plate bellows structure pipe like the bellows type is effective. That is, as shown in FIG. 3, a stationary flange 61 and a movable flange 62 are disposed such that they are opposed to each other with the drive shaft 56 interposed therebetween, and bellows 63 are disposed between the stationary flange 61 and the movable flange 62. In FIG. 3, the same elements as those shown in FIG. 1 are designated with the same symbols and explanation thereof will be omitted.

According to this structure, even if atmosphere enters the cleaning apparatus 1 from peripheries of the drive shaft 56, since the atmosphere enters a space surrounded by the stationary flange 61, the movable flange 62 and the bellows 63, the movable flange 62 is pushed upward and the bellows 63 is merely extended and the atmosphere does not enter a cleaning chamber 68 of the cleaning apparatus 1. Therefore, the substrate-to-be-cleaned 2 is not exposed to the atmosphere which enters. Similarly, a stationary flange 64 and a movable flange 65 are opposed to each other such as to surround a drive shaft 57, and bellows 66 are disposed between the stationary flange 64 and the movable flange 65.

In the drainage system, it is preferable to dispose a drainage trap such as a U-shaped pipe generally used for sewage, and it is preferable to delete the residence portion so that even when outside air is mixed, gas and water can efficiently be discharged.

The drainage openings 22 and 23 and the discharge openings 28, 29 and 30 may commonly be used, but when a large amount of cleaning liquid is used at the time of cleaning, cleaning liquid stays in the drainage openings 22 and 23, and there is an adverse possibility that the pressure in the cleaning apparatus 1 is varied. Thus, it is necessary to take a countermeasure. For example, a mechanism for holding the pressure in the cleaning apparatus 1 is disposed.

In this embodiment, two drainage systems in the classifying manner, i.e., the acid/alkali/organic water distribution system and the general drainage system are shown, but if the number of drainage systems in the classifying manner is increased to three or four, it is only necessary that the induction walls are disposed in accordance with the number of the drainage systems and the drainage openings and the discharge openings may be disposed in accordance with the necessary number, and the number of discharge system and the number of induction walls can freely be set.

Next, the cleaning liquid injection means will be explained.

Cleaning liquid supply pipes 32 and 33 are disposed in the container 3. The cleaning liquid supply pipes 32 and 33 are connected to an upper portion of a cleaning liquid injection arm 35 connected to the cleaning apparatus by a rotation support portion 34, and are connected to upper nozzles 36 and 37 such that the cleaning liquid supply pipes 32 and 33 are located above the substrate-to-be-cleaned 2. A drive motor 38 is disposed below the rotation support portion 34. If the drive motor 38 is driven, the cleaning liquid injection arm 35 is moved such as to draw an arc on an upper portion of the substrate-to-be-cleaned 2 around the rotation support portion 34. If cleaning liquid is supplied from the cleaning liquid supply pipes 32 and 33, desired cleaning liquids can be injected toward the surface-to-be-cleaned of the substrate-to-be-cleaned 2 from the upper nozzles 36 and 37, respectively. The cleaning liquid supply pipes 32 and 33, the upper nozzles 36 and 37, the rotation support portion 34, the cleaning liquid injection arm 35 and the drive motor 38 correspond to the cleaning liquid injection means of the present invention. The gas supply means 31 is connected to the cleaning liquid injection means, gas residence near the rotation support portion 34 of the cleaning liquid injection means is reduced, and efficient gas replacement and atmosphere of a clean cleaning liquid injection mechanism are controlled.

Like the gas supply means 5, the gas supply means 31 comprises a combination for controlling a general gas flow rate having a pressure-reducing valve, a valve and a mass flow controller, but a flow rate control by means of pressure control can sufficiently be used. Concerning the gas supply pipe it is preferable to delete the gas residence portion. The gas supply opening is formed in a side surface of the cleaning apparatus near the rotation support portion 34, but this portion is not limited to this.

Discharging means of gas supplied from the gas supply means 31 is carried out by the gas discharge means 6 connected to the discharge openings 28 and 29 and the gas discharge means 7 connected to the discharge opening 30. In this case also, gas discharge means which is special for the gas supply means 31 may separately be disposed instead of the gas discharge means 6 and 7.

In the embodiment, supply system of two kinds of cleaning liquids (acid and superpure water) is shown, but when the number of kinds of the cleaning liquids is increased to three or four, it is only necessary that the cleaning liquid supply pipes may be increased in accordance with the necessary number, and the supply pipe is fixed to an upper portion of the cleaning liquid injection arm 35 and the upper nozzle is disposed in accordance with the necessary number. When it is necessary to divide a liquid injection system, since the liquid injection arm can be increased, the number of cleaning liquid supply pipes, the number of liquid injection arms and the number of upper nozzles can freely be set.

Instead of separately providing the gas supply means 5, the gas supply means 21 and the gas supply means 31, and they may be integrally formed and be used commonly. This reduces the total flow rate of necessary gas, and since ht number of machining steps of the container 3 is reduced, the running cost and the production cost can be reduced.

To realize efficient control of the cleaning apparatus atmosphere, it is preferable that the cleaning apparatus 1 does not have an opening or a window through which the cleaning apparatus 1 is in communication with outside except the gas supply opening, the gas discharge opening, the cleaning liquid supply opening, the drainage opening, the atmosphere measuring window and the pressure measuring window, and the cleaning apparatus 1 is of a hermetic structure which is cut off from outside. Therefore, all of members which constitute the outward appearance of the cleaning apparatus such as an upper plate, an outer wall and a lower plate of the cleaning apparatus are sealed with various sealing means such as an O-ring, a resin packing and a metal C-ring.

As an inner shape of the cleaning apparatus, it is preferable that the gas residence portion is deleted to realize the efficient control of the cleaning apparatus atmosphere, and it is preferable that the pressure in the cleaning apparatus is higher than that of the outside air to prevent outside air from being mixed.

It is preferable that the residence portion is deleted from the cleaning liquid supply pipe, and a portion which deaerates or adds gas is disposed in the cleaning apparatus or near the cleaning apparatus.

Next, the operation of the cleaning apparatus of the embodiment will be explained.

If the substrate-to-be-cleaned 2 is transferred onto the table 19 of the cleaning apparatus 1, the valve 8 of the gas discharge means 6 is opened to efficiently replace gas, and evacuation in the container 3 of the cleaning apparatus 1 is started by the vacuum pump 9 provided downstream of the valve 8. When it is confirmed that the pressure in the container 3 of the cleaning apparatus 1 is reduced to a desired level by the pressure measuring device 10, the valve 8 is closed and the evacuation is stopped.

Next, inert gas is introduced into the container 3 of the cleaning apparatus 1 by the gas supply means 5, the pressure in the cleaning apparatus 1 is measured by the pressure measuring device 10, and if it is confirmed that the pressure in the container 3 of the cleaning apparatus 1 is increased to a desired pressure level, the valve 14 disposed in the gas discharge means 7 is operated, and gas in the cleaning apparatus 1 is exhausted.

Next, the atmosphere in the container 3 of the cleaning apparatus 1 is measured by the atmosphere component measuring device 4. If concentration of moisture, organic matters or other gas component existing in the atmosphere in the container 3 is higher and desired atmosphere can not be obtained, the evacuation and introduction of inert gas are repeated more than two times until the desired atmosphere is obtained. If abnormality is found in concentration of flammable component, combustible component and oxdizer component by the atmosphere component measuring device 4 and there is a possibility of fire or explosion, the gas supply means 5 and the gas discharge means 6 and 7 are immediately operation in association with each other, the flammable component, the combustible component and the oxdizer component are discharged out from the cleaning apparatus 1, the concentration can be lowered to a safety level, and it is possible to prevent a fire. The atmosphere in the cleaning apparatus 1 is measured by the atmosphere component measuring device 4 at arbitrary timing.

After the atmosphere in the cleaning apparatus 1 is controlled to obtain a desired atmosphere, the cleaning operation is started. Cleaning operation using acid/alkali/organic solvent or agent, and cleaning operation using general water such as cleaning water and pure water are separately carried out.

The table 19 is rotated by the drive motor 20 through the rotation support member 18, the substrate-to-be-cleaned 2 on the table 19 is rotated, cleaning liquid such as acid/alkali/organic solvent or agent is supplied to the upper nozzle 36 from the cleaning liquid supply pipe 32, the cleaning liquid is injected to the substrate-to-be-cleaned 2 to carry out agent cleaning operation, cleaning liquid such as cleaning water and pure water is supplied to the upper nozzle 37 from the cleaning liquid supply pipe 33, cleaning water is injected to the substrate-to-be-cleaned 2 and the substrate-to-be-cleaned 2 is cleaned with water. At the same time, the drive motor 38 is driven, and the cleaning liquid injection arm 35 is moved such as to draw an arc on an upper portion of the substrate-to-be-cleaned 2 around the rotation support portion 34. With this, the substrate-to-be-cleaned 2 is cleaned. At that time, an atmosphere of a cleaning liquid injection mechanism which is being cleaned by the gas supply means 31 is controlled.

While the table 19 is rotating, inert gas is supplied into the cleaning apparatus 1 from the gas supply means 21 through the fluid bearing 17 and the rotation support member 18 and the pressure in the cleaning apparatus 1 is set higher than the outside air. With this outside air is prevented from being mixed into the cleaning apparatus 1 from the fluid bearing 17 and the rotation support member 18.

Gas supplied by the gas supply means 31 during the cleaning operation is supplied to the gas discharge means 7 from the discharge opening 30, and the gas is discharged into the outside air by opening the valve 14.

The cleaning liquid after the cleaning operation is divided into two, i.e., an acid/alkali/organic water distribution system and a general drainage system. The acid/alkali/organic solvent or agent cleaning liquid is discharged into the drainage opening 22 from a gap between the induction wall 24 and the induction wall 25 by moving the drive shaft 55 upward by the vertically driving motor 26 and by moving the induction wall 24 upward. The cleaning water is discharged into the drainage opening 23 from a gap below the induction wall 25 by moving the drive shaft 56 upward by the vertically driving motor 27 and by moving the induction wall 25 upward.

During the drainage processing, there is an adverse possibility that waste liquid is mixed into the discharge system. In the embodiment, the discharge openings 28, 29 and 30 and the drainage openings 22 and 23 are disposed at different height positions to prevent waste liquid of the drainage system from being mixed into the discharge openings 28, 29 and 30 of the discharge system.

After the cleaning operation using cleaning water, moisture may adhere to the substrate-to-be-cleaned 2, but since the substrate-to-be-cleaned 2 is rotating on the table 19, such moisture is shaken off and moisture does not remain on the substrate-to-be-cleaned 2.

Even if moisture is shaken off from the substrate-to-be-cleaned 2, a trace of moisture remains as a water mark in some cases. The water mark functions as contamination residue, and generates various problems such as oxidation of a substrate, re-contamination of a cleaned substrate and reduction of surface roughness of a substrate. To prevent the water mark from being generated, the atmosphere at the time of cleaning operation using cleaning water should be reduced in pressure. More specifically, the container 3 should be evacuated. If the cleaning operation is carried out using the cleaning water in the vacuum atmosphere, moisture is completely removed, and water mark does not remain. When the container 3 is evacuated, the atmosphere component may be dispersed into magnetic fluid and may enter the container 3 in some cases. Therefore, it is preferable that the pressure in the container 3 is set higher than that in the fluid bearing 17 and the pressure in the fluid bearing 17 is set higher than the atmospheric pressure.

Another method for preventing a water mark from being generated is a method in which an atmosphere at the time of the cleaning operation using the cleaning water is brought into a dry environment. More specifically, dry fluid having low dew point temperature of water is supplied into the container 3, and the dew point temperature of water in the container 3 is set lower than that of the atmosphere.

With the above operation, the cleaning operation of the substrate-to-be-cleaned 2 is completed.

In the cleaning apparatus of the embodiment, it is preferable to carry out the evacuation for efficiently replacing gas, but when it is difficult to secure an installation place of the vacuum pump 9 or two or more discharge systems can not be secured for evacuation discharging and general discharging, it is unnecessary to carry out the evacuation, and it is preferable that a discharging amount adjusting mechanism such as a discharging damper is disposed for adjusting the discharging flow rate for the discharge system.

To enhance the cleaning effect, when cleaning liquid is supplied to the substrate-to-be-cleaned 2, it is also possible to, if necessary, add ultrasound or clean a back surface for enhancing the clean degree of the substrate-to-be-cleaned 2 in accordance with clean degree or kind required for the substrate-to-be-cleaned 2.

To prevent electrification of the substrate-to-be-cleaned 2, it is preferable that the cleaning apparatus 1 has soft X-ray irradiating means or static electricity removing means as earth countermeasure of a cleaning apparatus constituting member.

In the embodiment, the cleaning apparatus has one atmosphere component measuring device, but the number of atmosphere component measuring devices is not limited, and several atmosphere component measuring devices may be disposed if necessary.

In the embodiment, for connection between the gas discharge means and the gas supply means which supplies inert gas to the container 3, the gas supply opening is formed in the ceiling of the container 3 and the gas discharge opening is formed in the bottom of the container 3, but the present invention is not limited to this only if gas can be supplied to and discharged from the container 3, and the connecting manner is not limited.

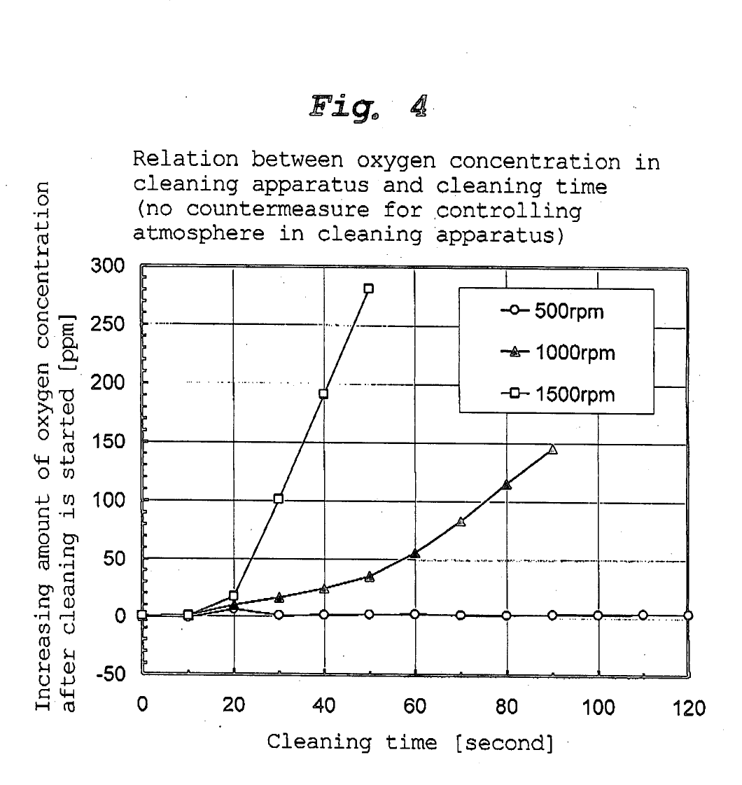

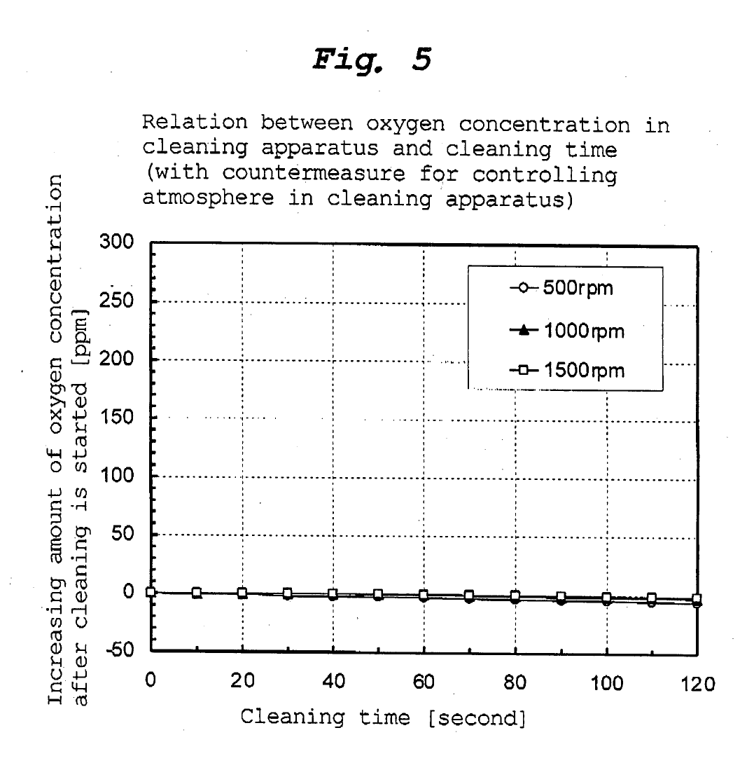

Next, effect of the cleaning apparatus of the present invention will be explained in detail based on results of concrete measurements. FIG. 4 shows a result of cleaning time dependency measurement of oxygen concentration in a cleaning apparatus of a single substrate type conventional rotation type cleaning apparatus in which gas is supplied from a portion above the substrate-to-be-cleaned and the gas is discharged from a portion below the substrate-to-be-cleaned when the cleaning apparatus of the present invention is not used. FIG. 5 shows a result of cleaning time dependency measurement of oxygen concentration in the cleaning apparatus when the cleaning apparatus of the present invention is used. In each of the drawings, the vertical axis shows an increase amount of the oxygen concentration in the cleaning apparatus after the cleaning operation is started, and the lateral axis shows the cleaning time. In the measurement, the increase amount of the oxygen concentration in the cleaning apparatus was measured when the number of revolutions of the substrate-to-be-cleaned was 500 rpm, 1000 rpm and 1500 rpm.

According to the cleaning apparatus of the present invention, the evacuation and discharging are carried out before the cleaning operation is started, and efficient gas replacement can be carried out. Therefore, the oxygen concentration can be reduced to about 50 ppm or less easily before the cleaning operation is started. Gas to be supplied is inert gas such as very pure nitrogen, and impurity concentration is 1 ppm or less. The component of the impurities is mainly moisture, and oxygen is not included almost at all.

As can be found from FIG. 4, when the cleaning apparatus of the present invention is not used, the increase amount of oxygen concentration is increased in accordance with the cleaning time, and the increasing tendency is higher as the number of revolutions of the substrate-to-be-cleaned is higher. Generally, in the single substrate type rotation cleaning operation, its cleaning time is several minutes, and the number of revolutions is 1500 to 2000 rpm. Thus, when the cleaning apparatus of the invention is not used, it can be found that oxygen of a few hundred ppm contamination is included in the cleaning apparatus after the cleaning operation is completed.

The increasing tendency of the oxygen concentration is increased as the number of revolutions of the substrate-to-be-cleaned becomes higher. It is estimated that this is because as the number of revolutions of the substrate-to-be-cleaned is increased, upward air current is generated from below the substrate-to-be-cleaned and outside air component is mixed from below. That is, a natural oxide film is formed by the interaction between the remaining moisture and oxygen after the cleaning operation is completed, and the substrate-to-be-cleaned is dotted with natural oxide films or water marks exist, there is an adverse possibility that the surface rough of the substrate-to-be-cleaned is increased, and the reliability of products and yield are deteriorated.

In recent years, to prevent a natural oxide film from being formed when a precision substrate is being cleaned and due to environmental problem caused by using a large amount of cleaning liquid such as acid/alkali/organic solvent, deaeration water obtained by deaerating remaining gas included in superpure water and function water in which desired very small amount of gas is solved after the deaeration to enhance the cleaning function are used for cleaning operation of precision substrates. The saturated dissolved oxygen concentration of superpure water at 25° C. in the atmosphere (oxygen concentration is about 21%) is about 8 ppm, and solubility of oxygen with respect to known passing water is not high so much. Therefore, a relation between the saturated dissolved oxygen concentration and the atmosphere oxygen concentration can be obtained by Henry's law that in gas whose solubility is not so high, the solubility of gas is proportional to partial pressure of component gas when the temperature is constant.

It is found that in deaerated water and function water, dissolved oxygen concentration after deaeration is reduced to 1 ppm or less. However, as shown in FIG. 4, in the conventional cleaning apparatus without using the cleaning apparatus of the present invention, oxygen of a few hundred ppm concentration is included after the cleaning operation is completed. Therefore, it can be found that oxygen concentration of solution which is reduced to 1 ppb after deaeration is increased to about 4, 20 and 40 ppb when the atmosphere oxygen concentration is 100, 500 and 1000 ppm from the Henry's law. There is a report that in superpure water in which the dissolved oxygen concentration is reduced to 40 ppb, it is increased to 600 ppb immediately after it is discharged into the atmosphere (oxygen concentration is about 21%). That is, even if the dissolved oxygen concentrations of the cleaning liquid and the superpure water are reduced to the lower limit and they are supplied to the cleaning apparatus, if oxygen exists in the cleaning apparatus atmosphere, there is a problem that the dissolved oxygen concentration is increased, a desired cleaning effect can not be obtained, and a natural oxide film is formed.

When the cleaning apparatus according to the present invention is used, as shown in FIG. 5, as a result of various countermeasures are taken in the atmosphere in the cleaning apparatus especially in the control of the oxygen concentration, the above-described problems are solved, and even if the cleaning time is increased, and even if the number of revolutions of the substrate-to-be-cleaned is increased, the oxygen concentration is not increased. Since the efficiency of gas replacement is enhanced, it is confirmed that the oxygen concentration is reduced with the cleaning time (i.e., gas replacement time). That is, if the various countermeasures are taken in the atmosphere in the cleaning apparatus especially in the control of the oxygen concentration, it is possible to clean the precision substrate in the clean atmosphere, atmosphere which suppress the formation of a natural oxide film is kept even after the cleaning operation and thus, it is obvious that it is possible to prevent contamination factor at the atomic or molecular level from adhering again after the cleaning operation, and to prevent a natural oxide film from being formed. The fact that the oxygen concentration of the atmosphere in the cleaning apparatus can be controlled means that it is possible to control atmosphere in the cleaning apparatus.

In the cleaning apparatus of the present invention, since it is possible to control the oxygen concentration in the cleaned atmosphere, it is possible to clean the precision substrate without increasing the dissolved oxygen concentration of cleaning liquid and superpure water which are supplied to the cleaning apparatus while reducing the dissolved oxygen concentration to the lower limit, and it is understood that a desired cleaning effect can be obtained.

Mist (vapor) of cleaning liquid generated when the substrate-to-be-cleaned is cleaned is abruptly discharged by taking various countermeasures for controlling the atmosphere in the cleaning apparatus, especially oxygen concentration, and it is needless to say that an atmosphere component measuring device such as an oximeter disposed in the cleaning apparatus is not damaged.

That is, in the present invention, it is possible to dispose the atmosphere component measuring device such as the oximeter in a cleaning apparatus where cleaning liquid or superpure water such as the acid/alkali/organic solvent is used.

### SECOND EMBODIMENT

Even when the substrate-to-be-cleaned 2 is cleaned in a clean atmosphere by the cleaning apparatus of the first embodiment, it is impossible to produce a high quality device such as a semiconductor with high yield if various countermeasures are not taken for controlling the atmosphere of the substrate-to-be-cleaned 2 such as a bringing in/out atmosphere of the substrate-to-be-cleaned 2, a clean drying processing atmosphere of the substrate-to-be-cleaned 2, a transportation atmosphere to a next step, a maintenance atmosphere of the substrate-to-be-cleaned and especially for controlling oxygen concentration.

The second embodiment is for solving such a problem, and is an example of a structure of the cleaning apparatus in which gas supply means for enhancing the quality, yield and throughput to produce a device such as a semiconductor, a cleaning apparatus having gas discharge means and an atmosphere component measuring device, a bringing in/out device whose atmosphere is controlled, a dryer, a connecting device, and devices before and after the cleaning operation are disposed.

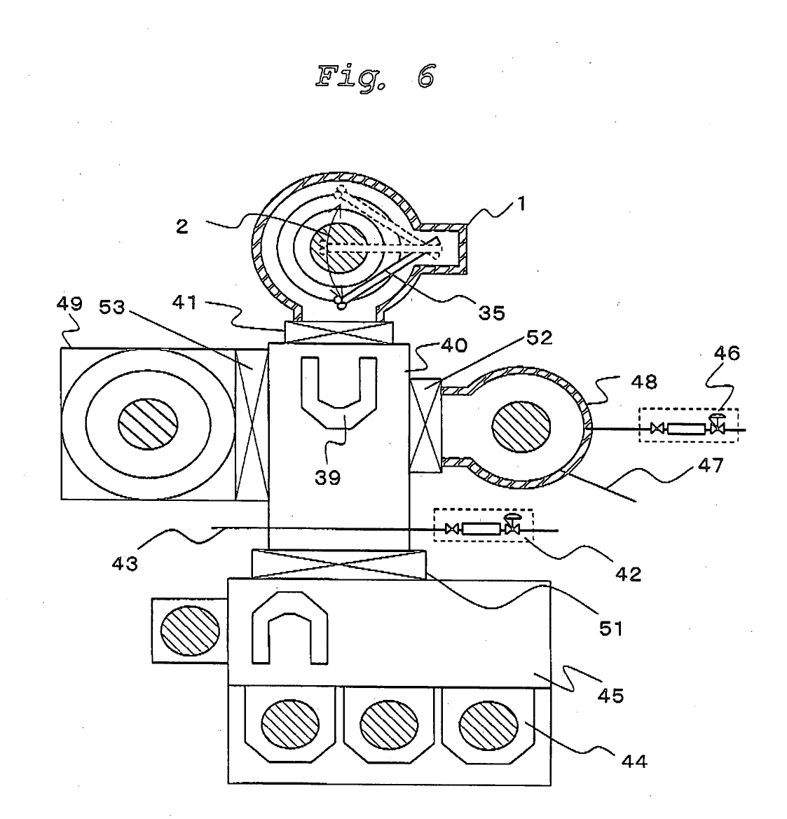

In FIG. 6, the cleaning apparatus 1 is the same as that explained in the first embodiment. A transfer device 40 having a transfer mechanism 39 is connected to the cleaning apparatus 1 through a cut-off mechanism 41 such as a gate valve. The transfer mechanism 39 transfers the substrate-to-be-cleaned 2 in and out for cleaning after the cleaning operation. The cut-off mechanism 41 can cut off an atmosphere in the transfer device 40 and an atmosphere in the cleaning apparatus 1 from each other. The transfer device 40 includes gas supply means 42 and gas discharge means 43 for controlling the atmosphere in the transfer device 40.

A special case 44 transfers or keeps the substrate-to-be-cleaned 2, and the special case 44 can detachably be attached to a connecting device 45. The connecting device 45 is connected to the transfer device 40 through a cut-off mechanism 51 such as a gate valve capable of cutting off an atmosphere in the transfer device 40 and an atmosphere in the connecting device 45 from each other.

A dryer 48 is connected to the transfer device 40 through a cut-off mechanism 52 such as a gate valve capable of cutting off an atmosphere in the transfer device 40 and an atmosphere in the dryer 48 for drying the substrate-to-be-cleaned 2 after it is cleaned. Gas supply means 46 and gas discharge means 47 for controlling atmosphere are connected to the dryer 48. The dryer 48 may be of a infrared lamp heating type or a vacuum drying type, and it type is not limited, but if a high temperature drying type dryer is used, a local oxide film is adversely formed by mist (vapor) of superpure water of cleaning liquid remaining on the substrate-to-be-cleaned and thus, attention must be paid. Each of the gas supply means 42 and 46 supplies a single kind of inert gas. Nitrogen or argon is preferable as the inert gas. A kind of gas may be selected in accordance with a kind of the substrate-to-be-cleaned 2 and a drying purpose and use of the substrate-to-be-cleaned 2 after it is cleaned, and mixed gas may be used instead of the single gas.

A device 49 which carries out steps before and after the cleaning operation of the substrate-to-be-cleaned 2 is connected through a cut-off mechanism 53 such as a gate valve capable of cutting of an atmosphere in the transfer device 40 and an atmosphere in the device 49 from each other.

Next, the operation will be explained.

In the normal state, the cut-off mechanisms 41, 51, 52 and 53 are closed, and the transfer device 40, the cleaning apparatus 1, the connecting device 45, the dryer 48 and the device 49 which carries out steps before and after the cleaning operation are maintained in a state where they are independent from each other.

First, pressures in the transfer device 40 and the connecting device 45 are previously adjusted to keep balance. Next, pressures in the transfer device 40 and the cleaning apparatus 1 are previously adjusted to keep balance. The cut-off mechanism 51 is opened, and a substrate-to-be-cleaned 2 to be cleaned is transferred into the transfer device 40 from the special case 44 of the connecting device 45 by the transfer mechanism 39. After the substrate-to-be-cleaned 2 is transferred into the transfer device 40, the cut-off mechanism 51 is closed, the cut-off mechanism 41 is opened, the transfer device 40 and the cleaning apparatus 1 are connected to each other, and the substrate-to-be-cleaned 2 is transferred into the cleaning apparatus 1 by the transfer mechanism 39. After the substrate-to-be-cleaned 2 is transferred into the cleaning apparatus 1, the cut-off mechanism 41 is closed and the substrate-to-be-cleaned 2 is cleaned by the cleaning apparatus 1. The carried out is carried out by the device and the method explained in the first embodiment. Since the cleaning apparatus 1 and the transfer device 40 are cut off from each other by the cut-off mechanism 41, a clean atmosphere is always maintained in the cleaning apparatus 1, and a cleaning step of high quality and high yield can be carried out.

If a drying operation is necessary after the cleaning operation is completed by the cleaning apparatus 1, the cut-off mechanism 41 is opened, the substrate-to-be-cleaned 2 is transferred into the transfer device 40 by the transfer mechanism 39, the cut-off mechanism 41 is closed, the cut-off mechanism 52 is opened and the substrate-to-be-cleaned 2 is transferred into the dryer 48. Pressures in the transfer device 40 and the dryer 48 are previously adjusted to keep balance before the cut-off mechanism 52 is opened. After the substrate-to-be-cleaned 2 is transferred into the dryer 48, the cut-off mechanism 52 is closed and the substrate-to-be-cleaned 2 is dried by the dryer 48. After the drying operation is completed, the cut-off mechanism 52 is opened, the substrate-to-be-cleaned 2 is transferred into the transfer device 40 and the cut-off mechanism 52 is closed. By the drying step in the dryer 48, mist (vapor) superpure water or cleaning liquid remaining on the cleaned substrate-to-be-cleaned 2 as a residue can be dried. Therefore, it is possible to maintain the clean degree of the substrate-to-be-cleaned 2 and to prevent a water mark from adhering.

When a substrate-to-be-cleaned 2 after it is cleaned and dried is subjected to a next step immediately, the cut-off mechanism 53 is opened and the substrate-to-be-cleaned 2 is transferred into the device 49 (device which carries out a step after the cleaning operation in this case) which carries out steps before and after the cleaning operation and then, the cut-off mechanism 53 is closed. When the substrate-to-be-cleaned 2 is temporarily kept, the cut-off mechanism 51 is opened, the substrate-to-be-cleaned 2 is transferred into the connecting device 45 and after the substrate-to-be-cleaned 2 is kept in the special case 44, the cut-off mechanism 51 is closed. Before the cut-off mechanisms 51 and 53 are opened, pressures between the transfer device 40 and the connecting device 45, and between the transfer device 40 and the device 49 which carries out steps before and after the cleaning operation are previously adjusted as in the previous embodiment.

The transfer device 40, the cleaning apparatus 1, the connecting device 45, the dryer 48 and the device 49 which carries out the steps before and after the cleaning operation are cut off from each other by the cut-off mechanisms 41, 51, 52 and 53. With this, it is possible to transfer the substrate-to-be-cleaned 2 out from the cleaning apparatus 1, transfer the substrate-to-be-cleaned 2 to a device of a next step, and keep the substrate-to-be-cleaned 2 in a state where the cleaning degree of the substrate-to-be-cleaned 2 is maintained. That is, it is considered that the conventional cleaning apparatus can not integrally (cluster) be formed with a drive process device such as a film forming step device and an etching step device since the mist (vapor) of the cleaning liquid or superpure water generated in the cleaning operation is not controlled and no countermeasures are taken for preventing outside air from being mixed. However, the cleaning apparatus of the embodiment can be integrally formed with the drive process device, and it is possible to enhance the quality, yield and throughput of production of devices such as semiconductors.

### THIRD EMBODIMENT

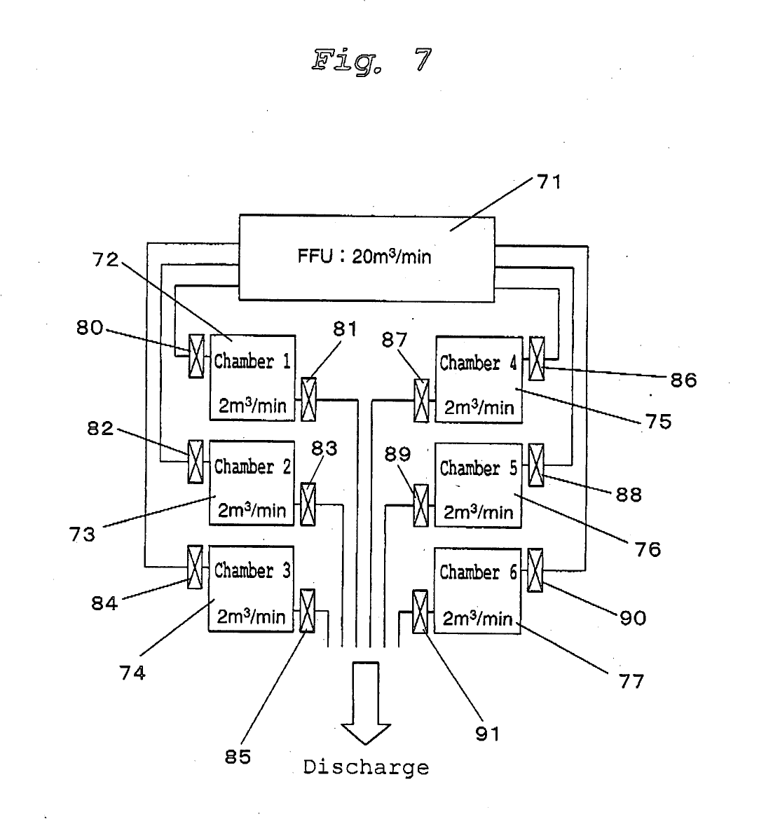

According to the third embodiment, a plurality of cleaning apparatuses 1 of the first embodiment are used, and a plurality of precision substrates such as semiconductor substrates, liquid crystal glass substrates and magnetic disks are cleaned at the same time. As shown in FIG. 7, six cleaning apparatuses 1 are used in this embodiment. Chambers 72 to 77 shows cleaning chambers of the cleaning apparatuses 1. Other portions of the cleaning apparatus 1 are the same as that of the first embodiment and thus, explanation thereof will be omitted.

A gas supply device 71 corresponds to the gas supply means 31 in FIG. 1. The gas supply device 71 is commonly provided for the chambers 72 to 77 of the cleaning apparatuses 1. When gas flow rates of the chambers 72 to 77 are 2 m³/min for example, it is enough if gas supply ability of the gas supply device 71 is 20 m³/min.

Inert gas supplied from the gas supply device 71 is supplied to the chamber 72 through a supply-side damper 80, to the chamber 73 through a supply-side damper 82, to the chamber 74 through a supply-side damper 84, to the chamber 75 through a supply-side damper 86, to the chamber 76 through a supply-side damper 88, and to the chamber 77 through a supply-side damper 90. Gas discharged from the chambers 72 to 77 is connected to discharge means (corresponding to the gas discharge means 6 and 7 in FIG. 1) to the chamber 72 through a discharge-side damper 81, to the chamber 73 through the discharge-side damper 83, to the chamber 74 through the discharge-side damper 85, to the chamber 75 through the discharge-side damper 87, to the chamber 76 through the discharge-side damper 89 and to the chamber 77 through the discharge-side damper 91. Openings of the supply-side dampers 80, 82, 84, 86, 88 and 90 and the discharge-side dampers 81, 83, 85, 87, 89 and 91 are independently controlled.

When cleaning operations of all of the chambers 72 to 77 are carried out, all of the dampers 80 to 91 are opened, and inert gas supplied from the gas supply device 71 flows through the chambers 72 to 77 and is discharged out.

A case where the cleaning operation in the chamber 74 is completed is now considered. If the cleaning step is completed, it is necessary to exchange a substrate-to-be-cleaned 2 to be cleaned. Hence, the supply-side damper 84 and the discharge-side damper 85 of the chamber 74 are closed, and the chamber 74 is separated from the gas supply device 71 and the discharge means (not shown). At that time, there is an adverse possibility that balance of inert gas supplied to other chambers 72, 73, 75, 76 and 77 from the gas supply device is lost, but the supply-side dampers 80, 82, 86, 88 and 90 and the discharge-side dampers 81, 83, 87, 89 and 91 of the chambers 72, 73, 75, 76 and 77 detect that the supply-side damper 84 and the discharge-side damper 85 of the chamber 74 are closed and they automatically adjust the openings, and automatically adjust the flow rates and thus the balance is not lost.

After the chamber 74 is separated from the gas supply device 71 and the discharge means, the substrate-to-be-cleaned 2 is taken out from the chamber 74 and a substrate-to-be-cleaned 2 which is to be newly cleaned is inserted for the next cleaning operation. When the cleaning operation in the chamber 74 is to be started, the closed supply-side damper 84 and discharge-side damper 85 are opened. In this case also, there is an adverse possibility that the balance of inert gas supplied from the gas supply device 71 to the other chambers 72, 73, 75, 76 and 77 is lost, but the supply-side dampers 80, 82, 86, 88 and 90 and the discharge-side dampers 81, 83, 87, 89 and 91 of the chambers 72, 73, 75, 76 and 77 detect that the supply-side damper 84 and the discharge-side damper 85 of the chamber 74 are opened, they automatically adjust the openings and automatically adjust the flow rates and thus, the balance is not lost.

The substrate-to-be-cleaned 2 is exchanged by the transfer mechanism 39 explained in the third embodiment.

The various countermeasures for preventing the contamination factor from adhering again and preventing the natural oxide film from being formed at the atomic or molecular level after cleaning operation explained in the first to third embodiment have respective effects, but it is preferable that all of the various countermeasures are taken to prevent the contamination factor from adhering again and to prevent the natural oxide film from being formed after the cleaning operation.

### FOURTH EMBODIMENT

In the first embodiment, the substrate-to-be-cleaned 2 is held on the table 19, the rotation support member 18 is rotated by the drive motor 20 and the substrate-to-be-cleaned 2 is rotated through the table 19. In the fourth embodiment, the substrate-to-be-cleaned is not directly held on the table, the a nozzle is provided on an upper surface of a support body which rotates around a rotation shaft, gas is supplied to the nozzle, and the substrate-to-be-cleaned 2 is supported in a non-contact manner by Verneuil's principle.

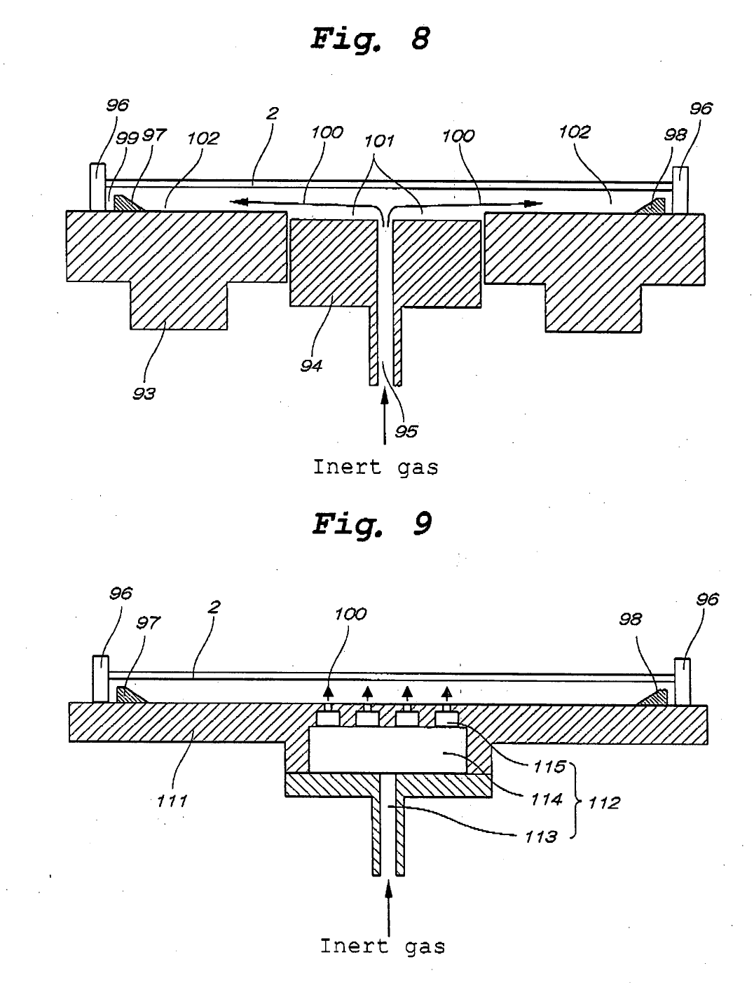

FIG. 8 is a sectional side view of a substrate-to-be-cleaned support portion. A cylindrical nozzle member 94 is disposed in a hollow portion of a hollow cylindrical chuck 93. The nozzle member 94 can vertically move. A plurality of pawls 96 project substantially vertically from outer periphery of an upper surface of the chuck 93. The pawls 96 are arranged circularly. The pawls 96 support a periphery of the substrate-to-be-cleaned 2. A ring projection 97 is disposed on an upper surface of the chuck 93 (table) inside of the circle by the plurality of pawls 96. That is, at least the inner diameter of the ring projection 97 is smaller than the outer diameter of the substrate-to-be-cleaned 2. The shape of the ring projection 97 is not limited, but it is preferable that the ring projection 97 has such a shape that a gap between an upper surface of the ring projection and the substrate-to-be-cleaned 2 is gradually reduced from inside to outside of the substrate-to-be-cleaned 2. The chuck 93 is rotated by a motor (not shown) in a state where the substrate-to-be-cleaned 2 is placed on the upper surface of the chuck 93.

The nozzle member 94 is formed at its central portion with a gas discharge hole 95. Inert gas such as nitrogen gas is discharged out from the gas discharge hole 95. The nozzle member 94 can move vertically in the hollow of the chuck 93 by a vertically driving source.

The substrate-to-be-cleaned 2 is placed on the upper surface of the chuck 93, the upper surface of the nozzle member 94 is held lower than the upper surface of the chuck 93, the substrate-to-be-cleaned 2 is separated away from the upper surface of the chuck 93, and the chuck 93 is rotated in a state where the substrate-to-be-cleaned 2 is placed on the upper surface of the chuck 93. If inert gas 100 is injected from the gas discharge hole 95 with a predetermined flow rate in this state, the substrate-to-be-cleaned 2 floats up from the upper surface of the chuck 93 and the ring projection 97, and the inert gas 100 flows on the back surface of the substrate-to-be-cleaned 2 from the gas discharge hole 95 along a passage 101 formed by a gap between the upper surface of the nozzle member 94 and the substrate-to-be-cleaned 2 and along a passage 102 formed by a gap between the upper surface of the chuck 93 and the substrate-to-be-cleaned 2. Further, in the vicinity of the periphery of the substrate-to-be-cleaned 2, the inert gas flows through a passage 98 formed by a gap between the upper surface of the ring projection 97 and the substrate-to-be-cleaned 2 and flows from outer side 99 of the ring projection 97 around the substrate-to-be-cleaned 2 to outside.

At that time, the gas discharge hole 95 has a small flow passage cross section and thus, flow velocity of the inert gas 100 is high, the passage 101 formed by the gap between the substrate-to-be-cleaned 2 and the upper surface of the nozzle member 94 around the gas discharge hole 95 has a great flow passage cross section and thus, flow velocity of the inert gas 100 is reduced, the flow passage cross section of the passage 102 formed by the gap between the substrate-to-be-cleaned 2 and the upper surface of the chuck 93 becomes slightly smaller and thus, the flow velocity of the inert gas 100 is slightly increased, the passage 98 formed by the gap between the substrate-to-be-cleaned 2 and the upper surface of the ring projection 97 has a very small flow passage cross section and thus the flow velocity of the inert gas 100 becomes very high. The inert gas 100 which passes through the passage 98 and reaches the outside of the ring projection 97 is dispersed outward from the outside 99 of the ring projection 97 and thus the flow velocity of the inert gas 100 is reduced. Thus, the pressure distribution on the back side of the substrate-to-be-cleaned 2 becomes negative in the passages 101 and 102 by the Verneuil's principle, the substrate-to-be-cleaned 2 is sucked downward by the passages 101 and 102, and the substrate-to-be-cleaned 2 is placed along the upper surface of the rotating chuck 93 in the non-contact manner.

The inert gas 100 has such a flow rate that the substrate-to-be-cleaned 2 can produce a negative pressure by the Verneuil's principle, and when the substrate-to-be-cleaned 2 is a silicon wafer having a diameter of 200 to 300 mm and a thickness of 0.7 mm, it is preferable that the flowrate is 50 liters/minute although this value varies depending upon the size and weight of the substrate-to-be-cleaned 2.

In this state, cleaning liquid flows from above the substrate-to-be-cleaned 2 to clean the substrate-to-be-cleaned 2. At that time, since the substrate-to-be-cleaned 2 rotates with rotation of the chuck 93, the cleaning liquid flows on the surface of the substrate-to-be-cleaned 2 in the outer peripheral direction to clean the surface of the substrate-to-be-cleaned 2. The cleaning liquid which reaches the periphery of the substrate-to-be-cleaned 2 is scattered outward from the surface of the substrate-to-be-cleaned 2, but since the pressure of the inert gas 100 outside of the ring projection 97 is small, a portion of the cleaning liquid flows around toward the back surface of the substrate-to-be-cleaned 2 and cleans the periphery of the back surface of the substrate-to-be-cleaned 2. The flowing around position at that time is changed by the flow rate of the inert gas 100, the position of the ring projection 97, a size of the flow passage cross section of the passage 98 formed by the gap between the substrate-to-be-cleaned 2 and the upper surface of the ring projection 97, and the number of revolutions of the substrate-to-be-cleaned 2. Therefore, it is possible to control the flowing around position of the cleaning liquid by adjusting these factors.

When there is no ring projection 97, since the flowing around position is not uniform, the back surface cleaning position shape becomes non-uniform. However, if the ring projection 97 is provided as in this embodiment, the flowing around position becomes uniform by control of the flow velocity of the inert gas 100 by adjusting the height of the position of the ring projection 97, the height of the ring projection 97 and the shape of the upper surface, and the shape of the back surface position shape can be uniform.

When it is desired that the cleaning liquid does not flow around toward the back surface of the substrate-to-be-cleaned 2, the flow velocity of the inert gas 100 passing through the passage 98 formed by the gap between the substrate-to-be-cleaned 2 and the upper surface of the ring projection 97 is further increased to increase the pressure, the position of the ring projection 97 is brought closer to the periphery of the substrate-to-be-cleaned 2, the number of revolutions of the substrate-to-be-cleaned 2 is increased. This can prevent the cleaning liquid from flowing around toward the back surface of the substrate-to-be-cleaned 2.

The position of the ring projection 97 can be adjusted by preparing a plurality of kinds of ring projections 97 having different diameters and by appropriately selecting and using the same.

In this embodiment, the substrate-to-be-cleaned 2 is explained in the chuck type by the Verneuil's principle, but a type for sucking a center portion of a back surface of the substrate-to-be-cleaned 2 may be employed. When the substrate-to-be-cleaned 2 is sucked in this manner, a plurality of gas discharging holes for injecting inert gas are formed at predetermined radial positions from the center of the substrate-to-be-cleaned 2.

### FIFTH EMBODIMENT

In the structure of the fourth embodiment, since the cleaning liquid flows from above the substrate-to-be-cleaned 2 to clean the substrate-to-be-cleaned 2, if the substrate-to-be-cleaned 2 is damaged during the cleaning operation, there is an adverse possibility that the cleaning liquid enters the gas discharge hole 95 of the nozzle member 94. The fifth embodiment is for solving this problem.

FIG. 9 is a sectional side view of a substrate-to-be-cleaned support portion of the fifth embodiment. The same elements as those shown in FIG. 8 are designated with the same symbols. In FIG. 9 the chuck 93 and the nozzle member 94 shown in FIG. 8 are integrally formed together, but they may be separated as different members as shown in FIG. 8.

A substrate-to-be-cleaned holding stage 111 corresponds to a structure in which the chuck 93 and the nozzle member 94 in FIG. 8 are integrally formed. A plurality of pawls 96 are arranged on an outer peripheral area on the upper surface of the substrate-to-be-cleaned holding stage 111 in a circular form. The pawls 96 support a periphery of the substrate-to-be-cleaned 2. A ring projection 97 is disposed inside of the circular formed by the plurality of pawls 96. That is, at least an inner diameter of the ring projection 97 is smaller than a diameter of an outer periphery of the substrate-to-be-cleaned 2.

The substrate-to-be-cleaned holding stage 111 is formed at its central portion with a gas discharge portion 112 corresponding to the gas discharge hole 95 in FIG. 8. The gas discharge portion 112 includes a gas introducing opening 113 which is in communication with a inert gas supply source, a gas chamber 114 in which inert gas introduced from the gas introducing opening 113 is temporarily stored, and one or more gas discharge holes 115 from which gas is injected from the gas chamber 114 to a portion below the substrate-to-be-cleaned 2. It is preferable that each of the gas discharge holes 115 has an injection passage whose diameter is smaller than that of an upstream side passage so that even if the substrate-to-be-cleaned 2 is damaged while the substrate-to-be-cleaned 2 is cleaned and cleaning liquid reaches the gas discharge holes 115, cleaning liquid does not enter the gas discharge holes 115, and the diameter of the gas injection passage is as small as 1 mm or smaller. Since it is difficult to form such a thin hole precisely with a single machining operation, the injection passage is formed as a countersunk hole as shown in FIG. 9.

If the diameter of the injection passage of the gas discharge holes 115 is small, when a flow rate of inert gas necessary for supporting the substrate-to-be-cleaned 2 by the Verneuil's principle is secured, the flow velocity of gas flowing through the gas discharge holes 115 becomes flow velocity close to the velocity of sound. As is known, the velocity of sound is the maximum flow velocity as fluid velocity, and the fluid velocity can not exceed the velocity of sound. That is, if inert gas is discharged from the gas discharge holes 115 at flow velocity close to the velocity of sound, even if the substrate-to-be-cleaned 2 is damaged during cleaning, it is possible to prevent cleaning liquid from entering the gas discharge hole 95 of the nozzle member 94.

When it is difficult to support the substrate-to-be-cleaned 2 by the Verneuil's principle and a flow rate of inert gas necessary to control the flowing around motion of cleaning liquid toward a back surface of the substrate-to-be-cleaned 2 can not be secured easily, a plurality of gas discharge holes 115 are provided as shown in FIG. 9. With this, it is possible to secure necessary flow rate of inert gas.

It is natural that the pawls 96 are arranged concentrically with a circumference of the substrate-to-be-cleaned 2 because fluctuation of rotation is not generated by deviation when the substrate-to-be-cleaned 2 is cleaned, but it is preferable that the number of pawls 96 is odd number instead of an even number so that the pawls 96 are not opposed to each other with respect to the center of the substrate-to-be-cleaned 2 and the pawls 96 are arranged through equal angles from one another. This structure has an effect that when the substrate-to-be-cleaned 2 is supported, stress applied to the pawls 96 of the substrate-to-be-cleaned 2 is moderated, and this prevent the substrate-to-be-cleaned 2 from being damaged.

As explained above, according to the present invention, the cleaning apparatus for cleaning a precision substrate includes gas supply means for controlling an atmosphere in a container where cleaning operation is carried out, especially a concentration of oxygen existing in the atmosphere, gas discharge means and an atmosphere component measuring device. With this, it is possible to control a contamination factor at the atomic or molecular level such as moisture, organic matter and other gas component existing in the atmosphere in the cleaning apparatus, and to prevent re-adhesion of contamination factor at the atomic or molecular level after cleaning operation, and to prevent a natural oxide film from being formed and to prevent the water mark.

Therefore, it is possible to clean a substrate-to-be-cleaned in a clean atmosphere, to maintain the clean degree of the substrate-to-be-cleaned, and to obtain a cleaning step in which high quality, high yield and safety against an explosion and a fire are secured.

A transfer device whose atmosphere is controlled, a dryer, a connecting device and devices for steps before and after the cleaning operation are disposed in the cleaning apparatus of the present invention. With this, it is possible to realize high quality, high yield and high throughput of production of devices such as semiconductors.

The substrate-to-be-cleaned is supported in a non-contact manner by Verneuil's principle, and a ring projection having a diameter smaller than an outer periphery of the substrate-to-be-cleaned is provided on a support surface of a chuck near a periphery of the substrate-to-be-cleaned. With this, it is possible to freely control the flowing around motion of cleaning liquid toward the back surface of the substrate-to-be-cleaned. Thus, it is possible to select, as required, uniform cleaning of the back surface of the substrate-to-be-cleaned and prevention of re-contamination of the back surface of the substrate-to-be-cleaned.

A discharge hole for inert gas is made thin when the substrate-to-be-cleaned is supported in the non-contact manner by the Verneuil's principle. With this, even when the substrate-to-be-cleaned is damaged while the substrate-to-be-cleaned is cleaned, it is possible to prevent cleaning liquid from entering the discharge hole of the inert gas.

### INDUSTRIAL APPLICABILITY

The present invention is preferably applied to a cleaning apparatus which cleans a precision substrate such as a semiconductor substrate, a liquid crystal glass substrate and a magnetic disk.

1: A cleaning apparatus for cleaning a substrate-to-be-cleaned such as a semiconductor substrate, a liquid crystal glass substrate and a magnetic disk in a container, the cleaning apparatus comprising atmosphere control means for controlling an atmosphere in said container, and a atmosphere component measuring device for measuring the atmosphere in said container.

2: The cleaning apparatus according to claim 1, wherein said atmosphere control means comprises gas supply means for supplying gas into said container, and gas discharge means for discharging the gas from said container.

3: The cleaning apparatus according to claim 1, wherein the atmosphere in the container is measured at any timing.

4: The cleaning apparatus according to claim 1, wherein an oxygen concentration is controlled by said atmosphere control means.

5: The cleaning apparatus according to claim 1, wherein said atmosphere component measuring device detects at least one of a flammable component, a combustible component and a oxdizer component.

6: The cleaning apparatus according to claim 5, wherein the oxdizer component is oxygen.

7: The cleaning apparatus according to claim 2, further comprising first gas supply means for equally supplying gas from a portion of said substrate-to-be-cleaned opposed to a surface-to-be-cleaned as said gas supply means.

8: The cleaning apparatus according to claim 7, further comprising a rotating/holding mechanism which holes said substrate-to-be-cleaned in its horizontal state and rotates the substrate-to-be-cleaned, and second gas supply means for supplying gas to said rotating/holding mechanism as said gas supply means.

9: The cleaning apparatus according to claim 7, further comprising a cleaning liquid injection mechanism for injecting cleaning liquid toward said surface-to-be-cleaned of said substrate-to-be-cleaned, and third gas supply means for supplying gas to control an atmosphere in said cleaning liquid injection mechanism as said gas supply means.

10: The cleaning apparatus according to claim 1, further comprising a drainage mechanism for draining cleaning waste liquid to desired one of an acid/alkali/organic drainage system and a general drainage system in a classified manner, wherein gas is discharged from said drainage mechanism.

11: The cleaning apparatus according to claim 10, wherein the drainage mechanism includes a plurality of cup-like induction walls arranged concentrically, wherein a drainage passage and a gas flow passage are formed by gaps between the cup-like induction walls, the gas flow passage includes a first passage having a great flow passage cross section formed between the cup-like induction walls, and a second passage having a small flow passage cross section connected to a downstream side of the first passage, and the flow passage cross section is designed such that a flow velocity of gas passing through the second passage becomes the maximum.

12: The cleaning apparatus according to claim 8, wherein said rotating/holding mechanism includes a table which is disposed in said container and which holds said substrate-to-be-cleaned, a rotation shaft for rotating said table, and a fluid bearing for holding said rotation shaft, a pressure in said container is set higher than the pressure of said fluid bearing, and the pressure of said fluid bearing is set higher than atmospheric pressure.

13: The cleaning apparatus according to claim 10, wherein said drainage mechanism includes a drive shaft for independently vertically moving a plurality of cup-like induction walls, a stationary flange and a movable flange are disposed such as to surround said drive shaft, and bellows are disposed between said stationary flange and said movable flange.

14: The cleaning apparatus according to claim 1, wherein a pressure of an atmosphere in said container is reduced.

15: The cleaning apparatus according to claim 1, wherein a dew point temperature of water in an atmosphere in said container can be controlled.

16: The cleaning apparatus according to claim 1, further comprising a rotating/holding mechanism which holds said substrate-to-be-cleaned in its horizontal state and rotates the substrate-to-be-cleaned, wherein said rotating/holding mechanism includes a table for holding said substrate-to-be-cleaned, a gas discharge hole for supplying inert gas is formed between said substrate-to-be-cleaned and said table, the inert gas to be supplied from said gas discharge hole is discharged from an outer periphery of said substrate-to-be-cleaned, and a ring projection having an inner diameter smaller than the outer periphery of said substrate-to-be-cleaned is provided on said table.

17: The cleaning apparatus according to claim 16, wherein said gas discharge hole has an injection passage having a diameter smaller than that of an upstream side passage through which the inert gas is supplied.

18: A cleaning system using the cleaning apparatus according to claim 1, comprising a transfer device having a transfer mechanism which transfers said substrate-to-be-cleaned into and out from said cleaning apparatus, a cut-off mechanism for cutting off an atmosphere in said transfer device and an atmosphere in said cleaning apparatus from each other, and atmosphere control means for controlling the atmosphere in said transfer device.

19: The cleaning system according to claim 18, wherein said atmosphere control means comprises gas supply means for supplying gas into said transfer device, and gas discharge means for discharging out the gas from said transfer device.

20: The cleaning system according to claim 18, wherein a connecting device to which a special case is freely detachably attached is connected to said transfer device through a cut-off mechanism for cutting off an atmosphere in said transfer device, and said special case transfers and stores the substrate-to-be-cleaned.

21: The cleaning system according to claim 18, wherein a dryer for drying said substrate-to-be-cleaned is connected to said transfer device through a cut-off mechanism for cutting off an atmosphere in said transfer device, and said dryer includes atmosphere control means for controlling an atmosphere in said dryer.

22: The cleaning system according to claim 21, wherein said atmosphere control means comprises gas supply means for supplying gas into said dryer, and gas discharge means for discharging the gas from said dryer.

23: The cleaning system according to claim 21, wherein one or more devices which carry out a step before or/and after a cleaning operation of said substrate-to-be-cleaned is connected to said transfer device through a cut-off mechanism for cutting off an atmosphere in said transfer device.

24: A cleaning system using the cleaning apparatus according to claim 2, wherein said gas supply means is connected to each one of gas supply openings of said plurality of cleaning apparatuses through dampers which can freely be controlled, and said gas discharge means is connected to each one of gas discharge openings of said plurality of cleaning apparatuses through said dampers.

25: A cleaning method for cleaning a substrate-to-be-cleaned using the cleaning apparatus according to claim 1, comprising a step for evacuating said container, a step for stopping the evacuating step when a pressure in said container is reduced to a desired level, a step for introducing inert gas into said container and discharging gas in said container when the pressure in said container is increased to a predetermined pressure level, a step for measuring the atmosphere in said container and controlling the atmosphere to a predetermined atmosphere, a step for rotating said substrate-to-be-cleaned and injecting a predetermined cleaning liquid to said substrate-to-be-cleaned while flowing inert gas into said container, and a step for draining the cleaning liquid after cleaning to a plurality of drainage systems in a classified manner.
